(19) United States
(12) Patent Application Publication
(10) Pub. No.: US 2024/0387566 A1
(43) Pub. Date: Nov. 21, 2024

(54) DISPLAY PANEL AND DISPLAY DEVICE

(71) Applicant: Wuhan Tianma Microelectronics Co., Ltd., Wuhan (CN)

(72) Inventors: Chao YU, Wuhan (CN); Yanni CAI, Wuhan (CN); Suping XI, Wuhan (CN)

(73) Assignee: Wuhan Tianma Microelectronics Co., Ltd., Wuhan (CN)

(21) Appl. No.: 18/786,045

(22) Filed: Jul. 26, 2024

(30) Foreign Application Priority Data
Jul. 28, 2023 (CN) 202310948729.0
May 31, 2024 (CN) 202410706243.0

(51) Int. Cl. H01L 27/12; G09G 3/32; H01L 25/075; H01L 25/16

(52) U.S. Cl. CPC H01L 27/1244; G09G 3/32; H01L 25/0753; H01L 25/167; G09G 2310/0267; G09G 2330/023

(57) ABSTRACT

A display panel includes a substrate and driver circuits disposed on one side of the substrate. A driver circuit includes at least two transistors. Gates of two transistors are connected to different control signal terminals. The display panel further includes shielding structures disposed on one side of the substrate facing the driver circuit. The shielding structures include shielding sub-structures each of which at least partially overlaps a channel region of one of the two preceding transistors. Different shielding sub-structures are connected to different potential signal terminals.

### CROSS-REFERENCE TO RELATED APPLICATION(S)

This application claims the priority of a Chinese Patent Application No. 202410706243.0, filed on May 31, 2024, and the priority of a Chinese Patent Application No. 202310948729.0, filed on Jul. 28, 2023, the disclosure of which are incorporated herein by reference in their entireties.

### TECHNICAL FIELD

The present application relates to the field of display panel technology and, in particular, to a display panel and a display device.

### BACKGROUND

With the development of display technology, display panels have been widely applied in production and daily life. However, display panels in the related art still have some technical problems to be solved urgently.

### SUMMARY

Embodiments of the present application provide a display panel and a display device.

In the first aspect, embodiments of the present application provide a display panel. The display panel includes a substrate and drive arrays disposed on one side of the substrate and including transistors.

The display panel further includes shielding structures disposed on one side of the substrate facing the drive arrays, where each of the shielding structures includes at least one shielding sub-structure, and a shielding sub-structure among the at least one shielding sub-structure at least partially overlaps a channel region of a respective one of the transistors.

The shielding sub-structure is connected to a potential signal terminal.

In the second aspect, embodiments of the present application provide a display device. The display device includes the display panel described in the first aspect.

Embodiments of the present application provide a display panel.

### BRIEF DESCRIPTION OF DRAWINGS

FIG. 1 is a structural diagram of a display panel according to some embodiments of the present application.

FIG. 2 is a sectional view taken along a line A-A′ of FIG. 1.

FIG. 3 is a diagram of circuit elements of a driver circuit according to some embodiments of the present application.

FIG. 4 is a structural diagram of a driver circuit according to some embodiments of the present application.

FIG. 5 is a diagram of circuit elements of another driver circuit according to some embodiments of the present application.

FIG. 6 is a structural diagram of another driver circuit according to some embodiments of the present application.

FIG. 7 is a diagram of circuit elements of another driver circuit according to some embodiments of the present application.

FIG. 8 is a structural diagram of another driver circuit according to some embodiments of the present application.

FIG. 9 is a diagram of circuit elements of another driver circuit according to some embodiments of the present application.

FIG. 10 is a structural diagram of another driver circuit according to some embodiments of the present application.

FIG. 11 is a diagram of circuit elements of another driver circuit according to some embodiments of the present application.

FIG. 12 is a structural diagram of another driver circuit according to some embodiments of the present application.

FIG. 13 is a structural diagram of another display panel according to some embodiments of the present application.

FIG. 14 is a diagram of circuit elements of another driver circuit according to some embodiments of the present application.

FIG. 15 is a diagram of circuit elements of another driver circuit according to some embodiments of the present application.

FIG. 16 is a diagram of circuit elements of another driver circuit according to some embodiments of the present application.

FIG. 17 is a diagram of circuit elements of a peripheral driver circuit according to some embodiments of the present application.

FIG. 18 is a sectional view taken along a line B-B′ of FIG. 1.

FIG. 19 is a structural diagram of another display panel according to some embodiments of the present application.

FIG. 20 is a diagram of the layer structure of a peripheral driver circuit according to some embodiments of the present application.

FIG. 21 is a diagram of a partial structure of FIG. 20.

FIG. 22 is a diagram of another partial structure of FIG. 20.

FIG. 23 is a diagram of circuit elements of another peripheral driver circuit according to some embodiments of the present application.

FIG. 24 is another sectional view taken along a line B-B′ of FIG. 1.

FIG. 25 is a diagram of the layer structure of another peripheral driver circuit according to some embodiments of the present application.

FIG. 26 is a diagram of a partial structure v of FIG. 25.

FIG. 27 is a diagram of another partial structure of FIG. 25.

FIG. 28 is a diagram of circuit elements of another peripheral driver circuit according to some embodiments of the present application.

FIG. 29 is another sectional view taken along a line B-B′ of FIG. 1.

FIG. 30 is another sectional view taken along a line B-B′ of FIG. 1.

FIG. 31 is another sectional view taken along a line C-C′ of FIG. 19.

FIG. 32 is a structural diagram of another display panel according to some embodiments of the present application.

FIG. 33 is a sectional view taken along a line I-I′ of FIG. 32.

FIG. 34 is a sectional view taken along a line K-K′ of FIG. 32.

FIG. 35 is a structural diagram of another display panel according to some embodiments of the present application.

FIG. 36 is a structural diagram of another display panel according to some embodiments of the present application.

FIG. 37 is a structural diagram of another display panel according to some embodiments of the present application.

FIG. 38 is a structural diagram of another display panel according to some embodiments of the present application.

FIG. 39 is a structural diagram of a display device according to some embodiments of the present application.

### DETAILED DESCRIPTION

It is to be noted that terms such as “first” and “second” in the description, claims, and drawings of the present application are used for distinguishing between similar objects and are not necessarily used for describing a particular order or sequence. It is to be understood that data used in this manner are interchangeable in appropriate cases so that embodiments of the present application described herein can be implemented in an order not illustrated or described herein. In addition, terms such as “including”, “having”, and any other variations thereof are intended to encompass a non-exclusive inclusion. For example, a system, product, or device that includes a series of units not only includes the expressly listed steps or units but may also include other units that are not expressly listed or are inherent to such a product or device.

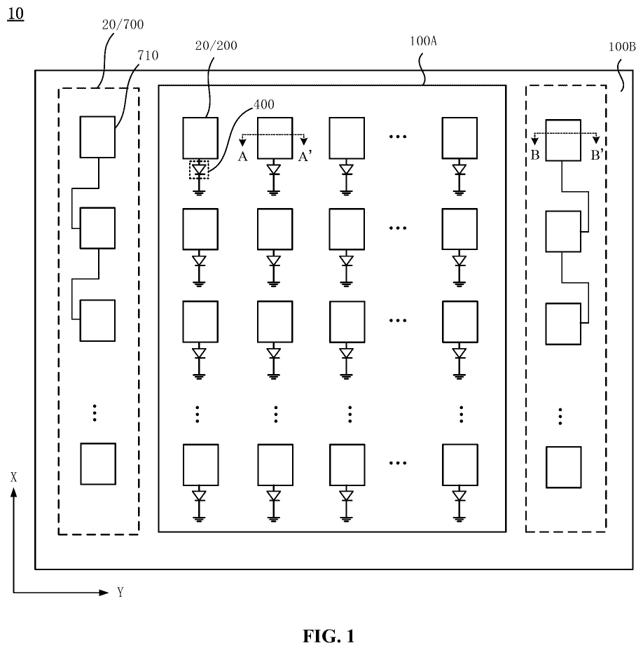

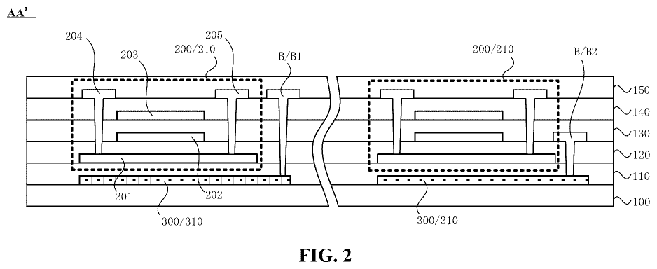

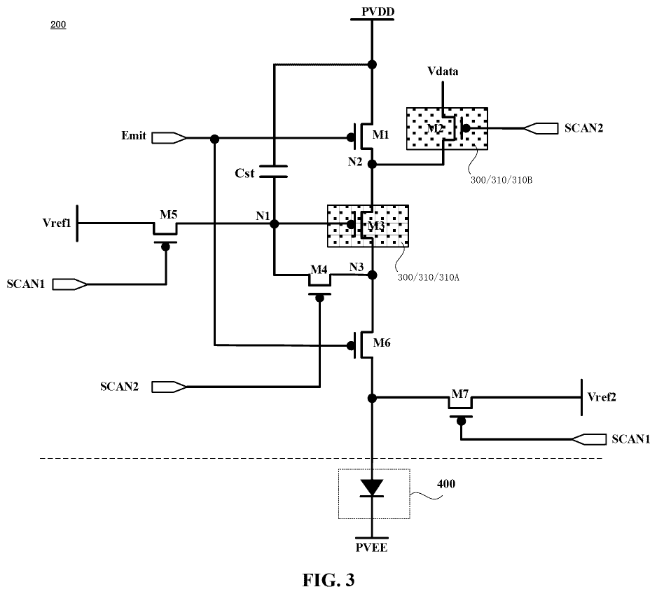

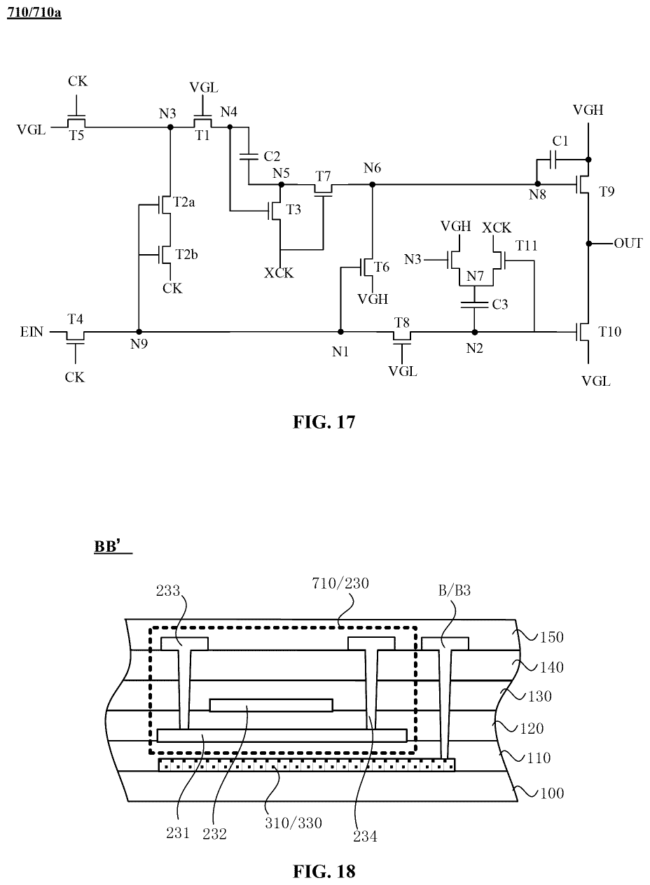

FIG. 1 is a structural diagram of a display panel according to some embodiments of the present application. FIG. 2 is a sectional view taken along a line A-A′ of FIG. 1. FIG. 3 is a diagram of circuit elements of a driver circuit according to some embodiments of the present application. FIG. 17 is a diagram of circuit elements of a peripheral driver circuit according to some embodiments of the present application. FIG. 18 is a sectional view taken along a line B-B′ of FIG. 1. Referring to FIGS. 1, 2, 3, 17, and 18, the embodiment of the present application provides a display panel 10. The display panel 10 includes a substrate 100 and one or more drive arrays 20 disposed on one side of the substrate 100. A drive array 20 includes one or more transistors (such as a transistor 210 in FIG. 2 and a first transistor 230 in FIG. 18). The display panel 10 further includes shielding structures 300 disposed on one side of the substrate 100 facing the drive arrays 20. Each shielding structure 300 includes at least one shielding sub-structure 310. A shielding sub-structure 310 at least partially overlaps a channel region of a respective transistor 210. The shielding sub-structure 310 is connected to a potential signal terminal B, implementing the effect of electronic shielding, thereby effectively preventing ions on one side of the substrate 100 from entering each active layer of each transistor 210, thus reducing the impact on the working of each channel region, thus guaranteeing the working stability of each transistor 210, guaranteeing the working stability of the drive arrays 20, alleviating situations such as the presence of an afterimage of the display panel 10, and guaranteeing the display effect of the display panel 10.

Drive arrays are included on one side of a substrate of the display panel and include transistors. Further, the display panel further includes shielding structures disposed on one side of the substrate facing the drive arrays. Each shielding structure includes at least one shielding sub-structure. A shielding sub-structure is connected to a potential signal terminal that can supply a potential signal to the shielding sub-structure. The shielding sub-structure connected to a potential is equivalent to a shielding layer which can effectively reduce the effect, for example, a threshold drift, on the transistor in different working environments, thus effectively guaranteeing the working stability of the transistor and thereby guaranteeing the display effect of the display panel.

A drive array 20 includes one or more transistors 210. Exemplarily, when the drive array 20 includes one or more driver circuits 200, arrangement manners of the driver circuits 200 are diversified, and a driver circuit 200 includes at least one transistor 210. When the drive array 20 includes one or more peripheral driver circuits 710, arrangement manners of the peripheral driver circuits 710 are also diversified, and a peripheral driver circuit 710 includes at least one transistor 210. The number and type of transistors 210 in a driver circuit 200 and the number and type of transistors 210 in a peripheral driver circuit 710 may be adjusted adaptively according to actual needs and are not specifically limited in the embodiment of the present application. The embodiment of the present application provides a display panel. A shielding sub-structure at least partially overlaps a channel region of a transistor and is connected to a potential signal terminal. The potential signal terminal may supply a potential signal to the shielding sub-structure. The shielding sub-structure connected to a potential is equivalent to a shielding layer which can effectively reduce the effect, for example, a threshold drift, on the transistor in different working environments, thus effectively guaranteeing the working stability of the transistor and thereby guaranteeing the display effect of the display panel.

Illustratively, the display panel 10 includes driver circuits 200 disposed on one side of the substrate 100. Referring to FIG. 1, a drive array 20 may include one or more driver circuits 200 or one or more peripheral driver circuits 710. A driver circuit 200 is electrically connected to a light-emitting element 400 to drive the light-emitting element 400 to display and emit light. A peripheral driver circuit 710 is configured to transmit a control signal (for example, a scan signal or a light emission control signal) to the driver circuit 200 to guarantee that the driver circuit 200 supplies a drive current to the light-emitting element 400, thereby guaranteeing the display effect of the display panel 10.

A drive array 20 includes one or more transistors 210. Exemplarily, referring to FIG. 2, when a drive array 20 includes one or more driver circuits 200, arrangement manners of the driver circuits 200 are diversified, and a driver circuit 200 includes at least one transistor 210. Referring to FIG. 18, when a drive array 20 includes one or more peripheral driver circuits 710, arrangement manners of the peripheral driver circuits 710 are also diversified, and a peripheral driver circuit 710 includes at least one transistor 210 (for example, a first transistor 230). The number and type of transistors in a driver circuit 200 and the number and type of transistors in a peripheral driver circuit 710 may be adjusted adaptively according to actual needs and are not specifically limited in the embodiment of the present application.

In some embodiments, a driver circuit 200 includes at least two transistors 210. Gates of two transistors 210 are connected to different control signal terminals. The display panel 10 further includes shielding structures 300 disposed on one side of the substrate 100 facing the driver circuit 200. The shielding structures 300 include shielding sub-structures 310, and each of the shielding sub-structures 310 at least partially overlaps a channel region of a respective one of the two transistors 210. Different shielding sub-structures 310 are connected to different potential signal terminals B.

Illustratively, the display panel includes the driver circuits 200 disposed on one side of the substrate 100. Referring to FIGS. 1 and 2, each of the driver circuits 200 is electrically connected to a light-emitting element 400. That is, by way of example, the driver circuit 200 in FIG. 1 is a pixel driving circuit for driving the light-emitting element 400 to perform display and light emission.

Optionally, a transistor 210 in a driver circuit 200 may be a low temperature poly-silicon (LTPS) transistor and has the advantages such as high switching speed, high carrier mobility, and low power. Further, a transistor 210 may also be an indium gallium zinc oxide (IGZO) transistor and has the advantages such as low production cost and low power consumption. When a driver circuit 200 includes both a low temperature poly-silicon transistor and an indium gallium zinc oxide transistor, that is, when an LTPO transistor and an IGZO transistor are combined, the display panel 10 including the driver circuit 200 is a low temperature polycrystalline oxide (LTPO). The LTPO display panel 10 has both the advantages of high resolution, high reaction speed, high brightness and high aperture ratio that are owned by an LTPS display panel and the advantages of low production cost and low power consumption that are owned by an IGZO display panel.

Illustratively, referring to FIG. 2, the display panel 10 includes the substrate 100, multiple layers on one side of the substrate 100 which include multiple insulating layers and multiple metal layers, and an insulating layer and a metal layer are alternately disposed. The multiple insulating layers and the multiple metal layers include the driver circuits 200. Exemplarily, the multiple insulating layers on one side of the substrate 100 may include a buffer layer 100, a first gate insulating layer 120, a first interlayer insulating layer 130, a second interlayer insulating layer 140, and a third interlayer insulating layer 150. The specific number and type of insulating layers may be adjusted adaptively according to the actual design requirements of display panel 10. Further, the driver circuit 200 may include multiple transistors 210. The specific number of transistors 210 is not specifically limited in the embodiment of the present application. Moreover, a transistor 210 may also include other structures, for example, an active layer 201, a gate 202, a capacitor layer 203, a source 204, and a drain 205. The specific layer structure of the transistor 210 may be adjusted adaptively according to an actual condition.

Illustratively, the driver circuit 200 may include at least two transistors 210. The gates of the two transistors 210 are connected to different control signal terminals. Exemplarily, the different control signal terminals may be a scan signal and a light emission control signal. That is, signals received by the gates of the two transistors 210 may differ in timing; in other words, the two transistors 210 in the driver circuit 200 may implement different functions.

Further, referring to FIG. 2, the driver arrays 20 further include the shielding structures 300 disposed on one side of the substrate 100 facing the driver circuits 200. Illustratively, each shielding structure 300 at least partially overlaps a channel region of a respective transistor 210. The channel region is a region in an active layer 201 that corresponds to a gate 202. Moreover, the shielding structures 300 may be connected to some potential signals, that is, electrically connected to some potential signal terminals B to implement the effect of electronic shielding, thereby effectively preventing ions on one side of the substrate 100 from entering each active layer 201 of each transistor 210, that is, reducing the impact on the working of each channel region, thus guaranteeing the working stability of each transistor 210, alleviating situations such as the presence of an afterimage of the display panel 10, and guaranteeing the display effect of the display panel 10. In the case where the working stability of a transistor 210 is affected when the active layer 201 of the transistor 210 is irradiated by light, for example, in the case where the transistor 210 is an indium gallium zinc oxide (IGZO) transistor, a respective shielding structure 300 may perform the function of shielding light and avoid a threshold drift of the transistor 210.

Further, different shielding sub-structures 310 may be provided for channel regions of the transistors 210 connected to different control signal terminals. Moreover, different shielding sub-structures 310 are connected to different potential signal terminals B (shown as B1 and B2 in FIG. 2). Illustratively, the transistors 210 connected to different control signal terminals may perform working modes of different states. Different working modes may refer to, for example, the on time of the transistors 210, the off time of the transistors 210, and different input signals when the transistors 210 are turned on, which may be specifically limited according to actual types of the transistors 210 and are not specifically limited here in the embodiment of the present application. Based on different working modes of the transistors 210, the shielding structures 300 may generate different shielding effects. That is, the arrangement in which different shielding sub-structures 310 are connected to different potential signal terminals guarantees the working stability of various transistors 210 and thus guarantees the overall display effect of the display panel 10.

Above all, for the display panel provided in the embodiment of the present application, the shielding structures corresponding to channel regions of different transistors are connected to different potential signal terminals, specifically reducing the effect of different transistors in different working environments, effectively guaranteeing the working of the transistors, and thereby guaranteeing the display effect of the display panel.

FIG. 3 is a diagram of circuit elements of a driver circuit according to some embodiments of the present application. Referring to FIGS. 2 and 3, the driver circuit 200 includes a drive transistor M3 and a switch transistor. A gate of the drive transistor M3 and a gate of the switch transistor are connected to different control signal terminals. An output terminal of the drive transistor M3 is electrically connected to an anode of the light-emitting element 400. An input terminal of the switch transistor is electrically connected to a display signal line.

Illustratively, referring to FIG. 3, the driver circuit 200 may include the drive transistor M3 and the switch transistor. The output terminal of the drive transistor M3 is electrically connected to an anode of the light-emitting element 400. That is, the drive transistor M3 is configured to supply a drive current to the light-emitting element 400. The switch transistor may be any one or more of a light emission control transistor M1, a data write transistor M2, a threshold compensation transistor M4, an initialization transistor M5, a second light emission control transistor M6, or a reset transistor M7. That is, the input terminal of the switch transistor is electrically connected to the display signal line. Based on different types of switch transistors, the connected display signal line may be any one or more of, for example, a data signal line, a power signal line, or a reset signal line. The number and type of switch transistors may be adjusted adaptively according to different driver circuits 200, which is not specifically limited in the embodiment of the present application.

Further, the gate of the drive transistor M3 and the gate of the switch transistor are connected to different control signal terminals. Therefore, a shielding sub-structure 310 corresponding to the drive transistor M3 and a shielding sub-structure 310 corresponding to the switch transistor may be connected to different potential signal terminals B. It thus guarantees that different shielding sub-structures 310 may perform shielding adjustment to different degrees on channel regions of transistors 210 overlapping the sub-structures 310, thereby guaranteeing the working stability of different transistors 210. Exemplarily, referring to FIG. 2, different shielding sub-structures 310 are connected to different potential signal terminals B1 and B2. The shielding sub-structure 310 connected to a potential signal terminal B1 may overlap a channel region of the drive transistor M3. The shielding sub-structure 310 connected to a potential signal terminal B2 may overlap a channel region of the switch transistor.

Optionally, referring to FIG. 3, the embodiment of the present application is described with an example in which the driver circuit 200 includes “7T1C”, where “T” denotes a transistor and “C” denotes a capacitor, that is, a storage capacitor Cst in the embodiment of the present application. The driver circuit 200 includes a light emission control transistor M1, a data write transistor M2, a drive transistor M3, a threshold compensation transistor M4, an initialization transistor M5, a second light emission control transistor M6, a reset transistor M7, and a storage capacitor Cst. A first scan signal line SCAN1 controls the initialization transistor M5 of the driver circuit to be turned on or off and reset the gate potential of the drive transistor M3 when the initialization transistor M5 is turned on; that is, the first scan signal line SCAN1 transmits a first reset signal Vref1 to the initialization transistor M5 and resets a connection node (a first node N1) of the drive transistor M3, the initialization transistor M5, the threshold compensation transistor M4, and the storage capacitor Cst. A second scan signal line SCAN2 controls the data write transistor M2 of the driver circuit to be turned on or off and writes a data signal Vdata on a data signal line to the gate of the drive transistor M3 when the data write transistor M2 is turned on. The second scan signal line SCAN2 controls the threshold compensation transistor M4 to be turned on or off and performs compensation on the threshold voltage of the drive transistor M3 when the threshold compensation transistor M4 is turned on. Moreover, the first scan signal line SCAN1 controls the reset transistor M7 to be turned on or off and resets the anode of the light-emitting element 400 connected to the pixel circuit when the reset transistor M7 is turned on; that is, the first scan signal line SCAN1 transmits a second reset signal Vref2 to the anode of the light-emitting element 400. A light emission control signal line Emit controls the light emission control transistor M1 and the second light emission control transistor M6 to be turned on or off and transmits a first power signal PVDD to the light-emitting element 400 when the light emission control transistor M1 and the second light emission control transistor M6 are turned on, thus implementing the display and light emission of the light-emitting element 400. Exemplarily, light-emitting elements 400 may be, for example, organic light-emitting diodes (OLEDs), mini LEDs, micro LEDs, or quantum dot light-emitting diodes (QLEDs). The specific type of the light-emitting elements is not limited in the embodiment of the present application. Further, the light-emitting elements may include red light-emitting elements, green light-emitting elements, and blue light-emitting elements. The light-emitting elements of different colors may be in different arrangement manners, for example, in a diamond pixel arrangement, a standard RGB arrangement, a delta pixel arrangement, a pearl pixel arrangement, or a 2-in-1 pixel arrangement. The specific arrangement manner of the light-emitting elements of different colors is also not limited in the embodiment of the present application.

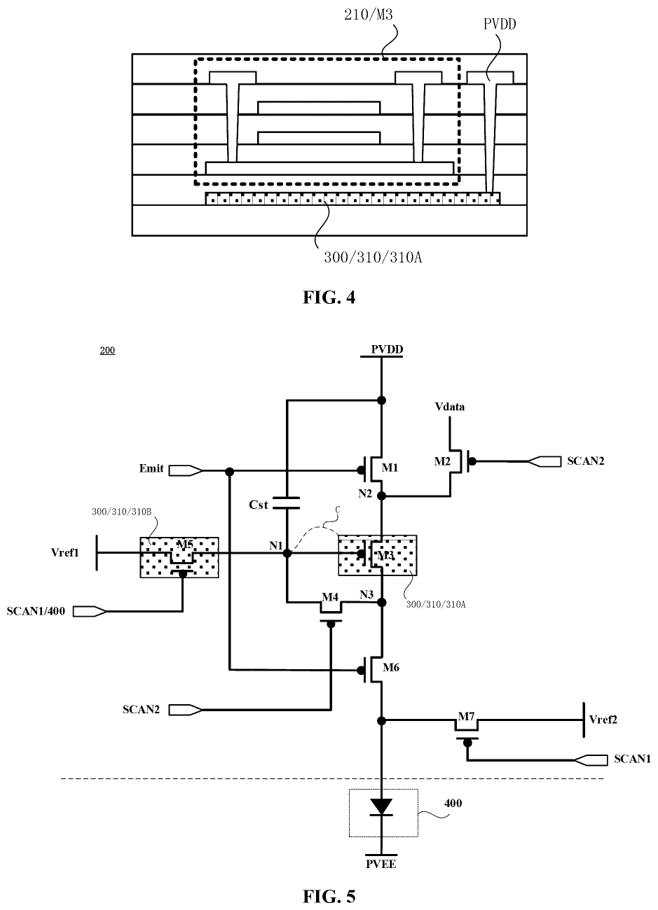

FIG. 4 is a structural diagram of a driver circuit according to some embodiments of the present application. Referring to FIGS. 3 and 4, an input terminal of the drive transistor M3 is electrically connected to a first power signal line PVDD. The shielding structures 300 include a first shielding sub-structure 310A at least partially overlapping the channel region of the drive transistor M3. The first shielding sub-structure 310A is connected to the first power signal line PVDD.

Illustratively, referring to FIG. 3, in the driver circuit 200, the input terminal of the drive transistor M3 receives a power signal input by the first power signal line PVDD. That is, when the drive transistor M3 is turned on, a first power signal is transmitted through the first power signal line PVDD. That is, a positive power signal is transmitted to the anode of the light-emitting element 400.

Further, referring to FIG. 4, the shielding structures 300 include the first shielding sub-structure 310A at least partially overlapping the channel region of the drive transistor M3, effectively preventing ions on one side of the substrate 100 from entering an active layer of the drive transistor M3, that is, reducing the impact on the working of the channel region, and thus guaranteeing the working stability of the drive transistor M3.

Further, referring to FIG. 4, the first shielding sub-structure 310A may be electrically connected to the first power signal line PVDD. That is, the first shielding sub-structure 310A and the input terminal of the drive transistor M3 are connected to the same potential signal terminal. That is, the first shielding sub-structure 310A is connected to a potential signal conforming to the working condition of the drive transistor M3. That is, the first shielding sub-structure 310A is connected to a potential signal at the input terminal of the drive transistor M3. Accordingly, the shielding effect better conforms to the working state of the drive transistor M3, thereby guaranteeing the working stability of the drive transistor M3, thereby guaranteeing that the light-emitting element 400 better emits light, and guaranteeing the display effect of the display panel 10.

FIG. 5 is a diagram of circuit elements of another driver circuit according to some embodiments of the present application. Referring to FIG. 5, an output terminal of a switch transistor is connected to a control terminal of the drive transistor M3 at the first node N1. The shielding structures 300 include a first shielding sub-structure 310A at least partially overlapping the channel region of the drive transistor M3. The first shielding sub-structure 310A is connected to the first node N1.

Illustratively, referring to FIG. 5, the switch transistor may be the initialization transistor M5. An output terminal of the initialization transistor M5 is connected to the control terminal of the drive transistor M3 at the first node N1. That is, the gate of the drive transistor M3 receives a signal at the first node N1 to control the working state of the drive transistor M3.

Further, referring to FIG. 5, the shielding structures 300 include the first shielding sub-structure 310A at least partially overlapping the channel region of the drive transistor M3, effectively preventing ions on one side of the substrate 100 from entering the active layer of the drive transistor M3, that is, reducing the impact on the working of the channel region, and thus guaranteeing the working stability of the drive transistor M3.

Further, referring to FIG. 5, the first shielding sub-structure 310A may be electrically connected to the first node N1 (A dashed line C in FIG. 5 shows the electrical connection between the first shielding sub-structure 310A and the first node N1). That is, the first shielding sub-structure 310A and the input terminal of the drive transistor M3 are connected to the same potential signal terminal. That is, the first shielding sub-structure 310A is also equivalent to being connected to a potential signal conforming to the working condition of the drive transistor M3. That is, the first shielding sub-structure 310A is connected to a potential signal at the control terminal of the drive transistor M3. Accordingly, the shielding effect better conforms to the working state of the drive transistor M3, thereby guaranteeing the working stability of the drive transistor M3, thereby guaranteeing that the light-emitting element 400 better emits light, and guaranteeing the display effect of the display panel 10.

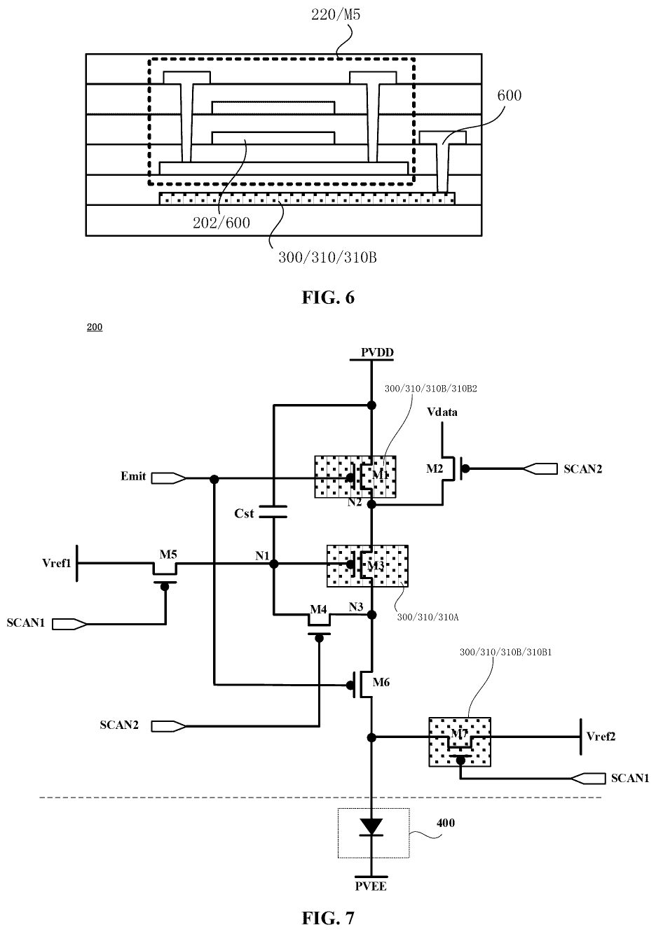

FIG. 6 is a structural diagram of another driver circuit according to some embodiments of the present application. Referring to FIGS. 5 and 6, a control terminal of the switch transistor (220 in FIG. 6) is electrically connected to a gating signal line (600 in FIG. 6). The shielding structures 300 include a second shielding sub-structure 310B at least partially overlapping the channel region of the switch transistor 220. The second shielding sub-structure 310B is connected to the gate signal line 600.

Illustratively, the switch transistor in FIG. 5 may be any one or more of the light emission control transistor M1, the data write transistor M2, the threshold compensation transistor M4, the initialization transistor M5, the second light emission control transistor M6, or the reset transistor M7. The number and type of switch transistors are adjusted adaptively according to the actual driver circuit 200. Further, the control terminal of the switch transistor is electrically connected to the gating signal line. That is, the gating signal line in FIG. 5 may be any one or more of the light emission control signal line Emit, the first scan signal line SCAN1, or the second first scan signal line SCAN2. That is, the gating signal line controls the on or off working state of the switch transistor.

Further, referring to FIGS. 5 and 6, the shielding structures 300 include the second shielding sub-structure 310B at least partially overlapping the channel region of the switch transistor, effectively preventing ions on one side of the substrate 100 from entering an active layer of the switch transistor, that is, reducing the impact on the working of the channel region, and thus guaranteeing the working stability of the switch transistor. Moreover, the second shielding sub-structure 310B is electrically connected to the gating signal line connected to the switch transistor corresponding to the shielding sub-structure 310B. In other words, the gating signal line connected to the gate of the switch transistor is also connected to the shielding sub-structure corresponding to the switch transistor. Therefore, it can guarantee that the second shielding sub-structure is connected to a potential signal conforming to the working condition of the switch transistor. That is, the shielding effect better conforms to the working state of the switch transistor, thereby guaranteeing the working stability of the switch transistor and guaranteeing the display effect of the display panel 10.

Exemplarily, FIG. 5 illustrates an example in which the switch transistor is the initialization transistor M5. In this case, a shielding structure 300 corresponding to the initialization transistor M5 includes the second shielding sub-structure 310B. Moreover, FIG. 6 also illustrates an example in which the switch transistor is the initialization transistor M5. The second shielding sub-structure 310B overlaps the channel region of the switch transistor 220. Further, a gating signal line 600 connected to a gate 202 of the initialization transistor M5 is the first scan signal line SCAN1. Moreover, the second shielding sub-structure 310B is also connected to the first scan signal line SCAN1. Therefore, such an arrangement guarantees that the shielding effect of the second shielding sub-structure 310B corresponding to the initialization transistor M5 better conforms to the working state of the initialization transistor M5, guaranteeing the working stability of the initialization transistor M5.

It is to be noted that FIGS. 5 and 6 illustrate an example of the initialization transistor M5. In fact, the switch transistor may be a transistor of another type. If the data write transistor M2 is taken for example, a gating signal line 600 connected to a second shielding sub-structure 310B corresponding to the data write transistor M2 may be the second scan signal line SCAN2. If the light emission control transistor M1 is taken for example, a gating signal line 400 connected to a second shielding sub-structure 310B corresponding to the light emission control transistor M1 may be the light emission control signal line Emit. Further, second shielding sub-structures 310B may be provided for multiple switch transistors respectively. That is, corresponding second shielding sub-structures 310B are provided for the initialization transistor M5 and the data write transistor M2 respectively and are connected to different gating signal lines 600. This is not specifically limited in the embodiment of the present application.

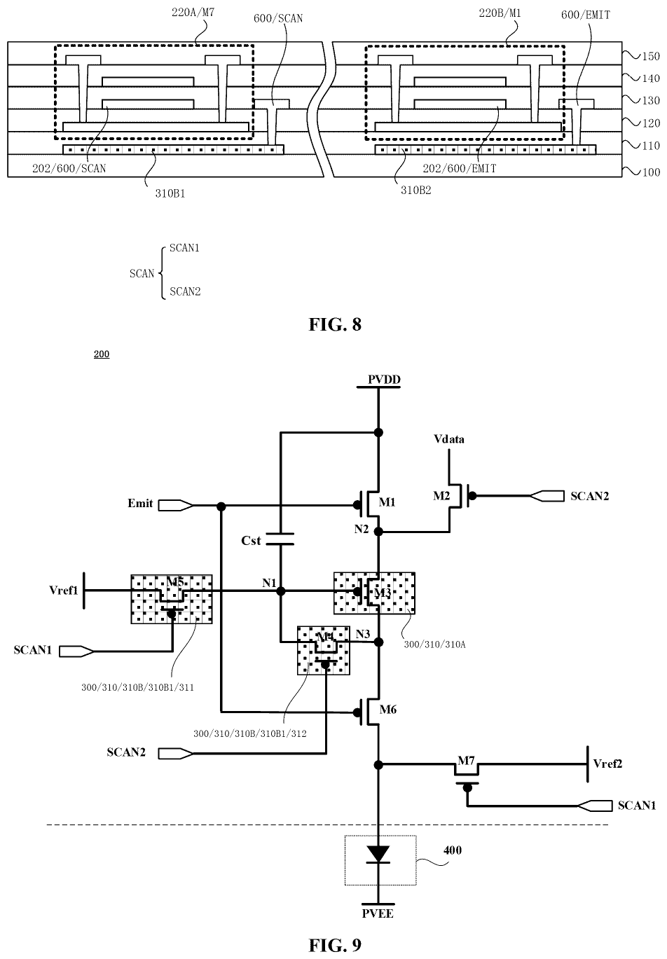

FIG. 7 is a diagram of circuit elements of another driver circuit according to some embodiments of the present application. FIG. 8 is a structural diagram of another driver circuit according to some embodiments of the present application. Referring to FIGS. 7 and 8, the driver circuit 200 includes a switch transistor. A control terminal of the switch transistor is electrically connected to a gating signal line (600 in FIG. 8). The gating signal line 600 includes a scan signal line SCAN and a light emission control signal line Emit. The switch transistor includes a scan switch transistor 220A and a light emission control switch transistor 220B. A control terminal of the scan switch transistor 220A is electrically connected to the scan signal line SCAN. A control terminal of the light emission control switch transistor 220B is electrically connected to the light emission control signal line Emit. Second shielding sub-structures 310B include a first shielding segment 310B1 and a second shielding segment 310B2. The first shielding segment 310B1 overlaps a channel region of the scan switch transistor 220A. The second shielding segment 310B2 overlaps a channel region of the light emission control switch transistor 220B. The first shielding segment 310B1 is connected to the scan signal line SCAN. The second shielding segment 310B2 is connected to the light emission control signal line Emit.

Illustratively, referring to FIG. 8, the switch transistor includes the scan switch transistor 220A and the light emission control switch transistor 220B. A gating signal line 600 connected to the control terminal of the scan switch transistor 220A (that is, a gate 202 of the scan switch transistor 220A), is the scan signal line SCAN. A gating signal line 600 connected to the control terminal of the light emission control switch transistor 220B (that is, a gate 202 of the light emission control switch transistor 220B), is the light emission control signal line Emit. Exemplarily, referring to FIG. 7, the scan switch transistor 220A may include any one or more of the data write transistor M2, the threshold compensation transistor M4, the initialization transistor M5, the reset transistor M7, and the like. The light emission control switch transistor 220B may include any one or more of the light emission control transistor M1, the second light emission control transistor M6, and the like. The specific number and type of scan switch transistors 220A and the specific number and type of light emission control switch transistors 220B may be adjusted adaptively according to the actual design requirements of the driver circuit 200, which is not specifically limited in the embodiment of the present application.

Exemplarily, FIG. 7 illustrates an example in which the scan switch transistor 220A is the reset transistor M7 and the light emission control switch transistor 220B is the light emission control transistor M1. Further, the gating signal lines 400 include the scan signal line SCAN and the light emission control signal line Emit. A control terminal of the reset transistor M7 (that is, a gate 202 of the reset transistor M7), is electrically connected to the scan signal line SCAN. A control terminal of the light emission control transistor M1 (that is, a gate 202 of the light emission control transistor M1) is electrically connected to the light emission control signal line Emit.

Further, corresponding shielding structures 300 are provided for the reset transistor M7 and the light emission control transistor M1 respectively, effectively preventing ions on one side of the substrate 100 from entering each active layer of each transistor, that is, reducing the impact on the working of each channel region, and thus guaranteeing the working stability of each transistor. Further, referring to FIG. 8, a shielding sub-structure 310 corresponding to the reset transistor M7 is the first shielding segment 310B1. A shielding sub-structure 310 corresponding to the light emission control transistor M1 is the second shielding segment 310B2. That is, FIG. 8 also illustrates an example in which the scan switch transistor 220A is the reset transistor M7 and the light emission control switch transistor 220B is the light emission control transistor M1.

Further, referring to FIGS. 7 and 8, the first shielding segment 310B1 disposed corresponding to a channel region of the reset transistor M7 is electrically connected to the scan signal line SCAN, thus guaranteeing that the shielding effect of the first shielding segment 310B1 corresponding to the reset transistor M7 better conforms to the working state of the reset transistor M7 and guaranteeing the working stability of the reset transistor M7. With the arrangement in which the second shielding segment 310B2 is disposed corresponding to a channel region of the light emission control transistor M1, the shielding effect better conforms to the working state of the light emission control transistor M1, guaranteeing the working stability of the light emission control transistor M1.

It is to be noted that FIGS. 7 and 8 illustrate an example of the light emission control transistor M1 and the reset transistor M7. Based on the number and type of scan switch transistors 220A in the actual driver circuit 200, a first shielding segment 310B1 may be disposed in each channel region of each scan switch transistor 220A. Moreover, a first shielding segment 310B1 and a control terminal of a respective scan switch transistor 220A are connected to the same potential signal. Alternatively, a second shielding segment 310B2 is disposed in each channel region of each light emission control switch transistor 220B. Moreover, a second shielding segment 310B2 and a control terminal of a respective light emission control switch transistor 220B are connected to the same potential signal.

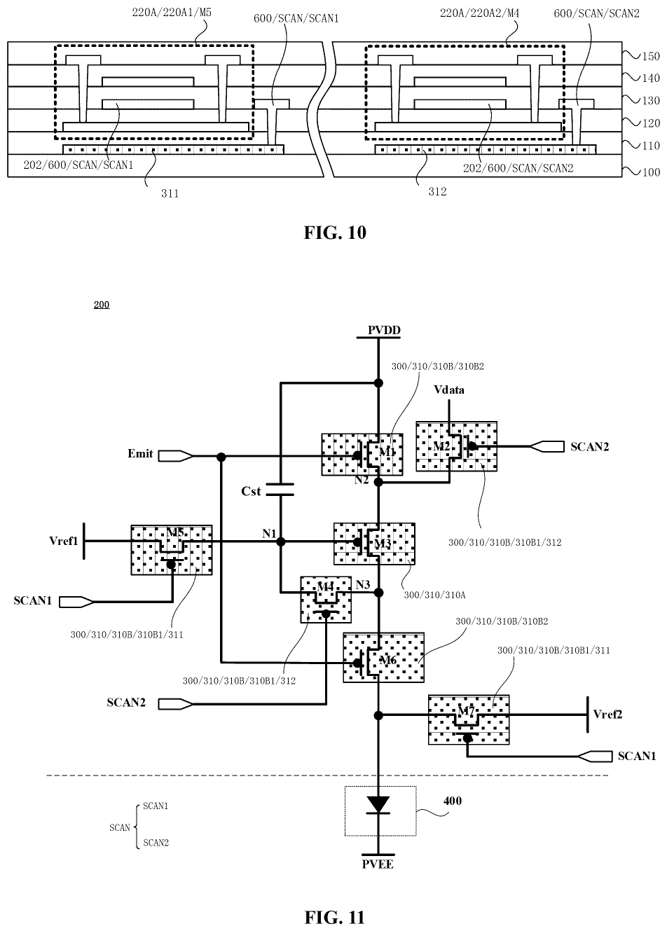

FIG. 9 is a diagram of circuit elements of another driver circuit according to some embodiments of the present application. FIG. 10 is a structural diagram of another driver circuit according to some embodiments of the present application. Referring to FIGS. 9 and 10, the scan signal line SCAN includes the first scan signal line SCAN1 and the second scan signal line SCAN2. The scan switch transistor 220A includes a first scan transistor 220A1 and a second scan transistor 220A2. A control terminal of the first scan transistor 220A1 is electrically connected to the first scan signal line SCAN1. A control terminal of the second scan transistor 220A2 is electrically connected to the second scan signal line SCAN2. The first shielding segment 310B1 includes a first shielding sub-segment 311 and a second shielding sub-segment 312. The first shielding sub-segment 311 overlaps a channel region of the first scan transistor 220A1. The second shielding sub-segment 312 overlaps a channel region of the second scan transistor 220A2. The first shielding sub-segment 311 is connected to the first scan signal line SCAN1. The second shielding sub-segment 312 is connected to the second scan signal line SCAN2.

Illustratively, the scan signal line SCAN includes the first scan signal line SCAN1 and the second scan signal line SCAN2. The first scan signal line SCAN1 and the second scan signal line SCAN2 may differ in timing. Alternatively, the first scan signal line SCAN and the second scan signal line SCAN2 may differ in high-level enabling and low-level enabling in enable stages. This is not specifically limited in the embodiment of the present application. Illustratively, the scan switch transistor 220A includes the first scan transistor 220A1 and the second scan transistor 220A2. The first scan transistor 220A1 is electrically connected to the first scan signal line SCAN1 and is turned on or off under the control of the first scan signal line SCAN1. The second scan transistor 220A2 is electrically connected to the second scan signal line SCAN2 and is turned on or off under the control of the second scan signal line SCAN2. Exemplarily, referring to FIG. 9, FIG. 9 illustrates an example in which the first scan signal line SCAN1 is the initialization transistor M5 and the second scan transistor 220A2 is the threshold compensation transistor M4.

Further, corresponding first shielding segments 310B1 are provided for the first scan transistor 220A1 and the second scan transistor 220A2 respectively, effectively preventing ions on one side of the substrate 100 from entering each active layer 201 of each transistor, that is, reducing the impact on the working of each channel region, and thus guaranteeing the working stability of each transistor. Further, referring to FIG. 10, a first shielding segment 310B1 corresponding to the first scan transistor 220A1 is the first shielding sub-segment 311. A first shielding segment 310B1 corresponding to the second scan transistor 220A2 is the second shielding sub-segment 312. That is, FIG. 10 also illustrates an example in which the first scan transistor 220A1 may be the initialization transistor M5 and the second scan transistor 220A2 may be the threshold compensation transistor M4.

Further, referring to FIGS. 9 and 10, the first shielding sub-segment 311 disposed corresponding to a channel region of the initialization transistor M5 is electrically connected to the first scan signal line SCAN1, thereby guaranteeing that the shielding effect of the first shielding sub-segment 311 corresponding to the initialization transistor M5 better conforms to the working state of the initialization transistor M5 and guaranteeing the working stability of the initialization transistor M5. With the arrangement in which the second shielding sub-segment 312 is disposed corresponding to a channel region of the threshold compensation transistor M4, the shielding effect better conforms to the working state of the threshold compensation transistor M4, guaranteeing the working stability of the threshold compensation transistor M4.

It is to be noted that FIGS. 9 and 10 illustrate an example of the initialization transistor M5 and the threshold compensation transistor M4. The number and type of first scan transistors 220A1 in the actual driver circuit 200 and the number and type of second scan transistors 220A2 in the actual driver circuit 200 may be adjusted adaptively.

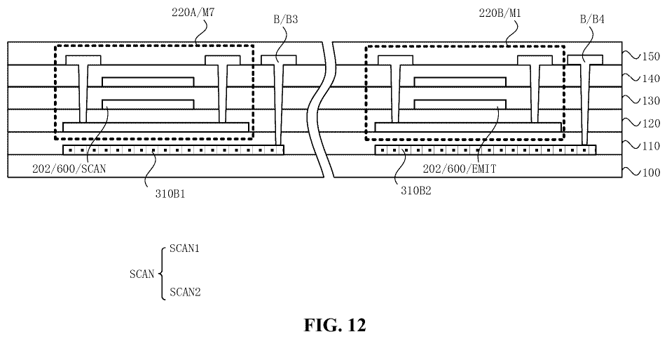

FIG. 11 is a diagram of circuit elements of another driver circuit according to some embodiments of the present application. FIG. 12 is a structural diagram of another driver circuit according to some embodiments of the present application. Referring to FIGS. 11 and 12, the driver circuit 200 includes a switch transistor. A control terminal of the switch transistor is electrically connected to a gating signal line. The gating signal line includes a scan signal line SCAN and a light emission control signal line Emit. The switch transistor includes a scan switch transistor 220A and a light emission control switch transistor 220B. A control terminal of the scan switch transistor 220A is electrically connected to the scan signal line SCAN. A control terminal of the light emission control switch transistor 220B is electrically connected to the light emission control signal line Emit. A switch transistor is configured to be turned on when the threshold voltage of the switch transistor is less than the gate-source voltage difference of the switch transistor. The second shielding sub-structure 310B includes a first shielding segment 310B1 and a second shielding segment 310B2. The first shielding segment 310B1 overlaps a channel region of the scan switch transistor 220A. The second shielding segment 310B2 overlaps a channel region of the light emission control switch transistor 220B. The voltage of a potential signal terminal B3 connected to the first shielding segment 310B1 is greater than the voltage of a potential signal terminal B4 connected to the second shielding segment 310B2.

Illustratively, referring to FIG. 11, a switch transistor in the driver circuit 200 is turned on when the threshold voltage of the switch transistor is less than the gate-source voltage difference of the switch transistor. That is, a control terminal of the switch transistor is in the on state when receiving a low-level signal. That is, the switch transistor may be a low temperature poly-silicon (LTPS) transistor and has the advantages such as high switching speed, high carrier mobility, and low power.

Further, the scan switch transistor 220A is configured to be turned on when the threshold voltage of the scan switch transistor 220A is less than the gate-source voltage difference of the scan switch transistor 220A, and the light emission control switch transistor 220B is configured to be turned on when the threshold voltage of the light emission control switch transistor 220B is less than the gate-source voltage difference of the light emission control switch transistor 220B. In this case, in combination with the working state of the scan switch transistor 220A and the working state of the light emission control switch transistor 220B, the first shielding segment 310B1 and the second shielding segment 310B2 may be adjusted to be connected to different potentials.

Illustratively, the scan switch transistor 220A may be one or more of the data write transistor M2, the threshold compensation transistor M4, the initialization transistor M5, or the reset transistor M7. The light emission control switch transistor 220B may be one or more of the light emission control transistor M1 or the second light emission control transistor M6. Moreover, in the overall drive timing of the driver circuit 200, the high-level timing of the scan signal line SCAN connected to the scan switch transistor 220A is longer than the low-level timing of the scan signal line SCAN connected to the scan switch transistor 220A. That is, the on duration of the scan switch transistor 220A is shorter than the off duration of the scan switch transistor 220A in the overall drive timing. The high-level timing of the light emission control signal line Emit connected to the light emission control switch transistor 220B is shorter than the low-level timing of the light emission control signal line Emit connected to the light emission control switch transistor 220B. That is, the on duration of the light emission control switch transistor 220B is longer than the off duration of the light emission control switch transistor 220B in the overall drive timing. In other words, the high-level duration of the scan signal line SCAN connected to the control terminal of the scan switch transistor 220A is relatively long, and the low-level duration of the light emission control signal line Emit connected to the light emission control switch transistor 220B is relatively long. The voltage of the potential signal terminal B connected to the first shielding segment 310B1 and the voltage of the potential signal terminal B connected to the second shielding segment 310B2 are adjusted based on the difference between a signal connected to the control terminal of the scan switch transistor 220A and a signal connected to the control terminal of the light emission control switch transistor 220B. That is, the voltage connected to the first shielding segment 310B1 corresponding to the channel region of the scan switch transistor 220A is adjusted to be greater than the voltage connected to the second shielding segment 310B2 corresponding to the channel region of the light emission control switch transistor 220B. Therefore, such an arrangement guarantees that the second shielding sub-structures 310B are connected to different potential signals according to the working states of corresponding switch transistors, guaranteeing the shielding effect of the second shielding sub-structures 310B and thereby guaranteeing the display effect of the display panel 10.

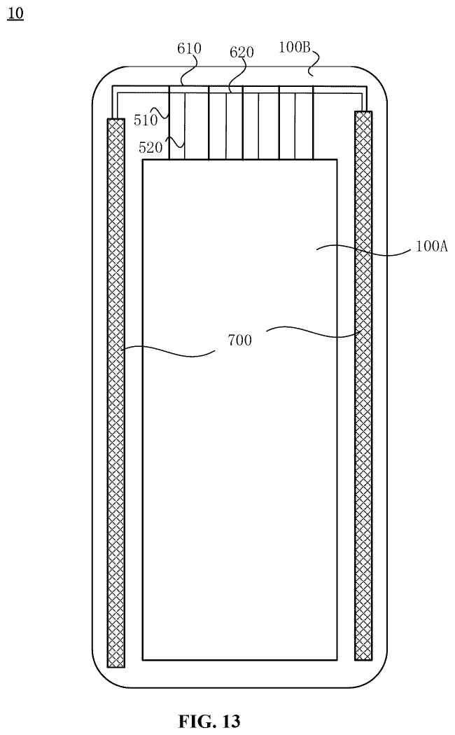

Optionally, FIG. 13 is a structural diagram of another display panel according to some embodiments of the present application. Referring to FIGS. 12 and 13, the display panel 10 further includes a peripheral circuit group 700, a first level signal line 410, and a second level signal line 420. The first level signal line 610 and the second level signal line 620 are electrically connected to the peripheral circuit group 700. The voltage of the first level signal line 610 is greater than the voltage of the second level signal line 620. The first shielding segment 310B1 is connected to the first level signal line 610. The second shielding segment 310B2 is connected to the second level signal line 620.

Illustratively, referring to FIG. 13, the display panel 10 further includes the peripheral circuit group 700. A peripheral driver circuit 710 may be a shift resister circuit. The peripheral circuit group 700 includes the first level signal line 610, the second level signal line 620, a first clock drive signal line, a second clock drive signal line, and the like. The voltage of the first level signal line 610 is greater than the voltage of the second level signal line 620. That is, the first level signal line 610 is a high-level drive signal line, and the second level signal line 620 is a low-level drive signal line.

Illustratively, the scan switch transistor 220A is configured to be turned on when the threshold voltage of the scan switch transistor 220A is less than the gate-source voltage difference of the scan switch transistor 220A, and the light emission control switch transistor 220B is configured to be turned on when the threshold voltage of the light emission control switch transistor 220B is less than the gate-source voltage difference of the light emission control switch transistor 220B. In this case, the voltage of the potential signal terminal B3 connected to the first shielding segment 310B1 is greater than the voltage of the potential signal terminal B4 connected to the second shielding segment 310B2. That is, the first shielding segment 310B1 may be connected to the first level signal line 610, and the second shielding segment 310B2 may be connected to the second level signal line 620.

Optionally, with continued reference to FIG. 13, the display panel 10 includes a display region 100A and a non-display region 100B surrounding at least a part of the display region 100A. The first shielding segment 310B1 located in the display region 100A is electrically connected through a first connection structure 510 to the first level signal line 610 located in the non-display region 100B. The second shielding segment 310B2 located in the display region 100A is electrically connected through a second connection structure 520 to the second level signal line 620 located in the non-display region 100B.

Illustratively, referring to FIG. 13, the display region 100A of the display panel 10 is configured to accommodate, for example, light-emitting elements to mainly implement the display function of the display panel 10. The non-display region 100B surrounding the display region 100A may be provided with the peripheral circuit group 700 and some wires to guarantee the display effect of the display panel 10.

Illustratively, the first level signal line 610 and the second level signal line 620 in the peripheral circuit group 700 may be electrically connected to the shielding structures 300 through connection structures or vias. Referring to FIG. 13, the first shielding segment 310B1 is electrically connected through the first connection structure 510 to the first level signal line 610 located in the non-display region 100B. The second shielding segment 310B2 is electrically connected through the second connection structure 520 to the second level signal line 620 located in the non-display region 100B. Such an arrangement guarantees that signals connected to different shielding structures 300 are different due to shielding different transistors, thereby guaranteeing the overall display effect of the display panel 10.

With continued reference to FIGS. 11 and 12, the input terminal of the drive transistor M3 is electrically connected to the first power signal line PVDD. A cathode of the light-emitting element 400 is electrically connected to a second power signal line PVEE. The first shielding segment 310B1 is connected to the first power signal line PVDD. The second shielding segment 310B2 is connected to the second power signal line PVEE.

Illustratively, referring to FIG. 11, the input terminal of the drive transistor M3 is electrically connected to the first power signal line PVDD and transmits the first power signal line PVDD to the anode of the light-emitting element 400. Moreover, the cathode of the light-emitting element 400 is electrically connected to the second power signal line PVEE. That is, the first power signal line PVDD is a positive power signal line, and the second power signal line PVEE is a negative power signal line. That is, the voltage of the first power signal line PVDD is greater than the voltage of the second power signal line PVEE.

Further, the scan switch transistor 220A is configured to be turned on when the threshold voltage of the scan switch transistor 220A is less than the gate-source voltage difference of the scan switch transistor 220A, and the light emission control switch transistor 220B is configured to be turned on when the threshold voltage of the light emission control switch transistor 220B is less than the gate-source voltage difference of the light emission control switch transistor 220B. In this case, the voltage of the potential signal terminal B3 connected to the first shielding segment 310B1 is greater than the voltage of the potential signal terminal B4 connected to the second shielding segment 310B2. That is, the first shielding segment 310B1 may be connected to the first power signal line PVDD, and the second shielding segment 310B2 may be connected to the second power signal line PVEE.

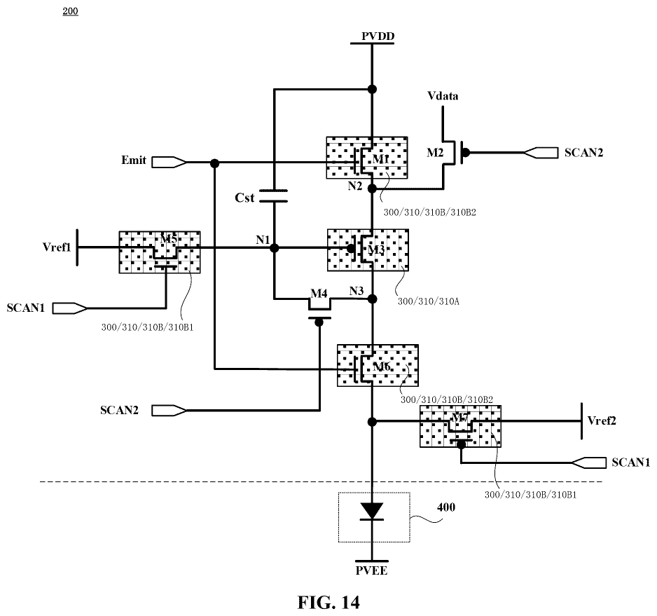

FIG. 14 is a diagram of circuit elements of another driver circuit according to some embodiments of the present application. Referring to FIGS. 12 and 14, the driver circuit 200 includes a switch transistor. A control terminal of the switch transistor is electrically connected to a gating signal line. The gating signal lines includes a scan signal line SCAN and a light emission control signal line Emit. The switch transistor includes a scan switch transistor 220A and a light emission control switch transistor 220B. A control terminal of the scan switch transistor 220A is electrically connected to the scan signal line SCAN. A control terminal of the light emission control switch transistor 220B is electrically connected to the light emission control signal line Emit. A switch transistor is configured to be turned on when the threshold voltage of the switch transistor is greater than the gate-source voltage difference of the switch transistor. The second shielding sub-structure 310B includes a first shielding segment 310B1 and a second shielding segment 310B2. The first shielding segment 310B1 overlaps a channel region of the scan switch transistor 220A. The second shielding segment 310B2 overlaps a channel region of the light emission control switch transistor 220B. The voltage of a potential signal terminal connected to the first shielding segment 310B1 is less than the voltage of a potential signal terminal connected to the second shielding segment 310B2.

Illustratively, referring to FIG. 14, a switch transistor in the driver circuit 200 is configured to be turned on when the threshold voltage of the switch transistor is greater than the gate-source voltage difference of the switch transistor. That is, a control terminal of the switch transistor is in the on state when receiving a low-level signal. That is, the switch transistor may be an indium gallium zinc oxide (IGZO) transistor and has the advantages such as low production cost and low power consumption.

Further, the scan switch transistor 220A is configured to be turned on when the threshold voltage of the scan switch transistor 220A is greater than the gate-source voltage difference of the scan switch transistor 220A, and the light emission control switch transistor 220B is configured to be turned on when the threshold voltage of the light emission control switch transistor 220B is greater than the gate-source voltage difference of the light emission control switch transistor 220B. In this case, in combination with the working state of the scan switch transistor 220A and the working state of the light emission control switch transistor 220B, the first shielding segment 310B1 and the second shielding segment 310B2 may be adjusted to be connected to different potentials.

Illustratively, the scan switch transistor 220A may be one or more of the data write transistor M2, the threshold compensation transistor M4, the initialization transistor M5, or the reset transistor M7. The light emission control switch transistor 220B may be one or more of the light emission control transistor M1 or the second light emission control transistor M6. FIG. 14 illustrates an example in which the scan switch transistor 220A includes the initialization transistor M5 and the reset transistor M7 and in which the light emission control switch transistor 220B includes the light emission control transistor M1 and the second light emission control transistor M6. Moreover, in the overall drive timing, the high-level timing of the scan signal line SCAN connected to the scan switch transistor 220A is shorter than the low-level timing of the scan signal line SCAN connected to the scan switch transistor 220A. That is, the on duration of the scan switch transistor 220A is shorter than the off duration of the scan switch transistor 220A in the overall drive timing. The high-level timing of the light emission control signal line Emit connected to the light emission control switch transistor 220B is longer than the low-level timing of the light emission control signal line Emit connected to the light emission control switch transistor 220B. That is, the on duration of the light emission control switch transistor 220B is longer than the off duration of the light emission control switch transistor 220B in the overall drive timing. In other words, the low-level duration of the scan signal line SCAN connected to the control terminal of the scan switch transistor 220A is relatively long, and the high-level duration of the light emission control signal line Emit connected to the light emission control switch transistor 220B is relatively long. The voltage of the potential signal terminal B connected to the first shielding segment 310B1 and the voltage of the potential signal terminal B connected to the second shielding segment 310B2 are adjusted based on the difference between a signal connected to the control terminal of the scan switch transistor 220A and a signal connected to the control terminal of the light emission control switch transistor 220B. That is, the voltage connected to the first shielding segment 310B1 corresponding to the channel region of the scan switch transistor 220A is adjusted to be less than the voltage connected to the second shielding segment 310B2 corresponding to the channel region of the light emission control switch transistor 220B. Therefore, such an arrangement guarantees that the second shielding sub-structures 310B are connected to different potential signals according to the working states of corresponding switch transistors, guaranteeing the shielding effect of the second shielding sub-structures 310B and thereby guaranteeing the display effect of the display panel 10.

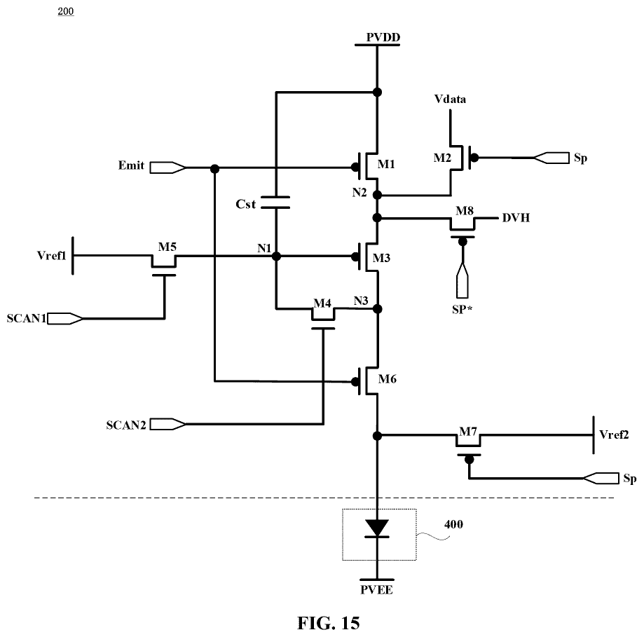

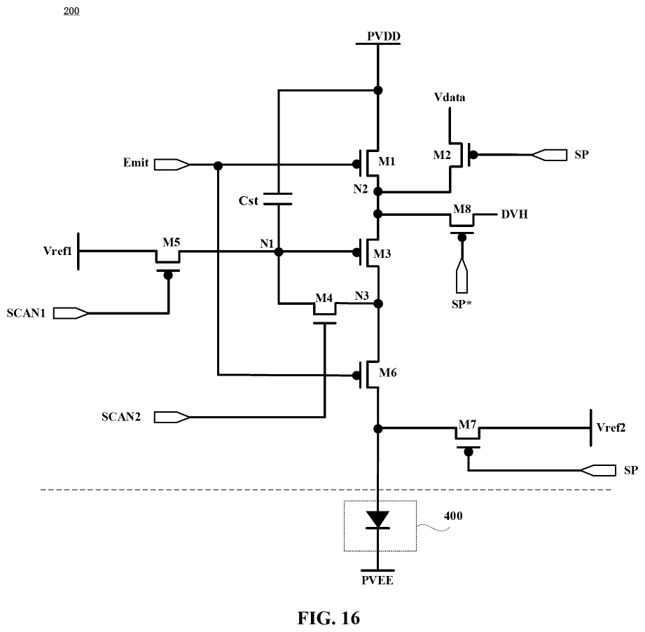

Further, FIG. 15 is a diagram of circuit elements of another driver circuit according to some embodiments of the present application. FIG. 16 is a diagram of circuit elements of another driver circuit according to some embodiments of the present application. Referring to FIGS. 15 and 16, in some embodiments of the present application, a driver circuit 200 may further include a bias transistor M8. Illustratively, a driver circuit 200 includes a light emission control transistor M1, a data write transistor M2, a drive transistor M3, a threshold compensation transistor M4, an initialization transistor M5, a second light emission control transistor M6, a reset transistor M7, a bias transistor M8, and a storage capacitor Cst. The working process of the driver circuit 200 is similar to the preceding process and is not repeated here. A control terminal of the bias transistor M8 is connected to a scan signal (shown as Sp* in the figure) to control the bias transistor M8 to be turned on or off, writes a reset signal (shown as DVH in the figure) when the bias transistor M8 is turned on, and performs bias adjustment on a second node N2.

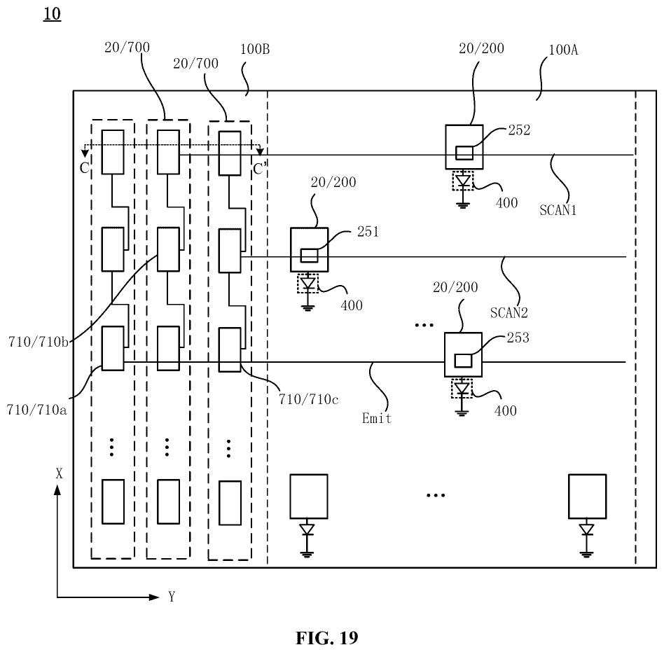

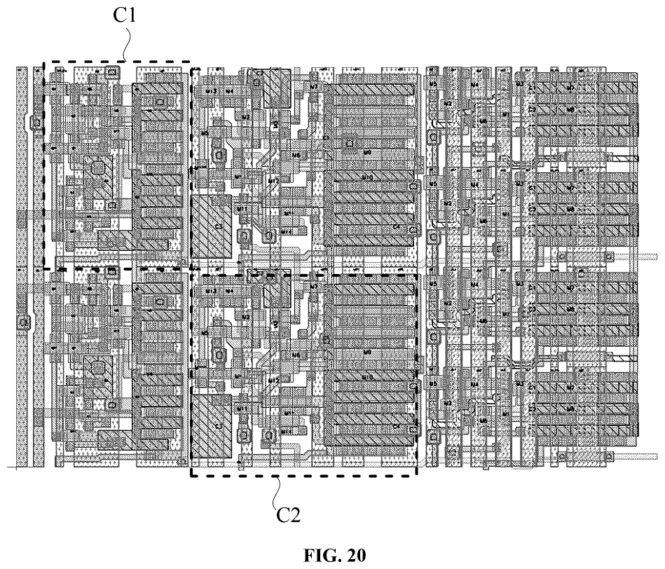

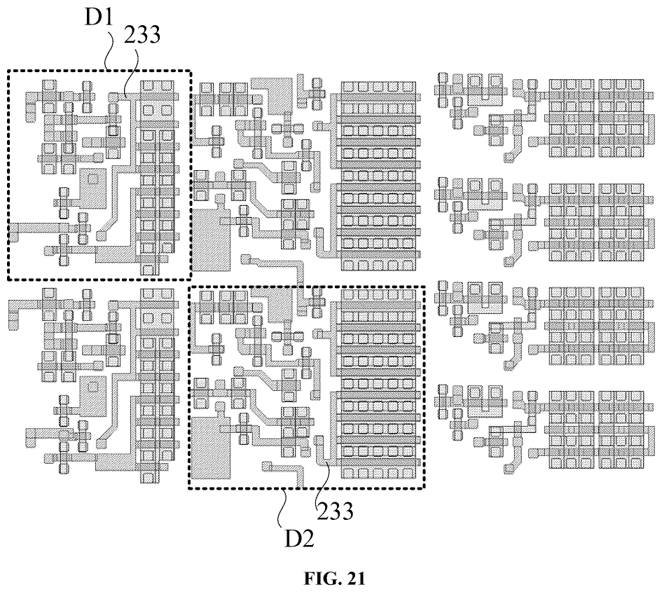

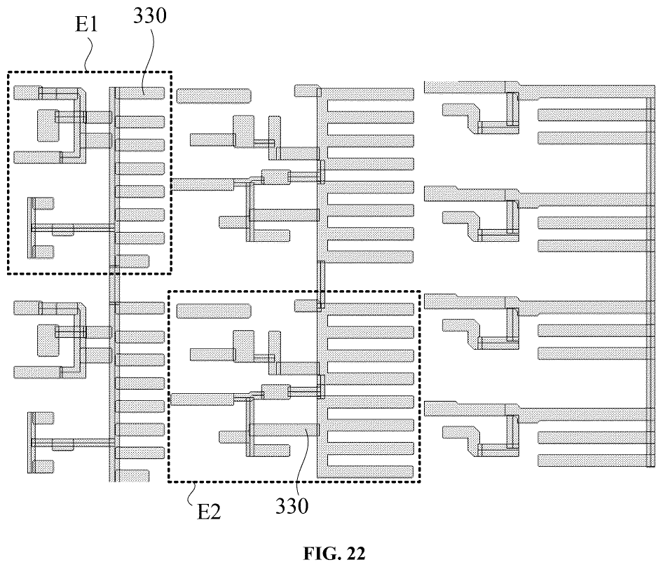

FIG. 19 is a structural diagram of another display panel according to some embodiments of the present application. FIG. 20 is a diagram of the layer structure of a peripheral driver circuit according to some embodiments of the present application. FIG. 21 is a partial structural view of FIG. 20. FIG. 22 is another partial structural view of FIG. 20. Referring to FIGS. 1 and 22, the display panel 10 includes a display region 100A and non-display regions 100B, and non-display regions 100B are located on two sides of the display region 100A respectively. The drive arrays 20 include driver circuits 200 located in the display region 100A and peripheral circuit groups 700 located in the non-display regions 100B. A peripheral circuit group 700 includes a plurality of peripheral driver circuits 710 arranged in a first direction X in a cascade manner. A peripheral driver circuit 710 includes a plurality of first transistors 230. The shielding structures 300 include shielding sub-structures 310. The shielding sub-structures 310 include a plurality of peripheral shielding sub-structures 330. Each peripheral shielding sub-structure 330 at least partially overlaps a channel region of a respective first transistor 230. The first direction X is parallel to a plane where the substrate 100 is located.

Illustratively, referring to FIG. 1 or 19, the display region 100A of the display panel 10 is configured to accommodate, for example, light-emitting elements 400 and the driver circuits 200 to mainly implement the display function of the display panel 10. The non-display regions 100B surrounding the display region 100A may be provided with the peripheral driver circuits 710 and some wires. The peripheral driver circuits 710 transmit control signals to the driver circuits 200 to guarantee that the driver circuits 200 drive the light-emitting elements 400, guaranteeing the display effect of the display panel 10. Illustratively, referring to FIG. 1 or 19, the peripheral circuit groups 700 are disposed in the non-display region 100B of the display panel 10. A peripheral circuit group 700 includes a plurality of peripheral driver circuits 710 arranged in the first direction X in a cascade manner.

A peripheral driver circuit 710 transmits a control signal (for example, a scan signal or a light emission control signal) to a transistor 210 of a driver circuit 200 and adjusts the working state of the transistor 210 through the control signal. Types and uses of transistors 210 in the driver circuit 200 are diversified. In this case, control signals required by different transistors 210 in the driver circuit 200 need to be adjusted. That is, types of peripheral driver circuits 710 are diversified. Exemplarily, referring to FIG. 3, a control signal input by the light emission control transistor M1 is a light emission control signal Emit; in this case, a peripheral driver circuit 710 is disposed to output the light emission control signal Emit to the driver circuit 200. A control signal input by the data write transistor M2 is the second scan signal line SCAN2; in this case, a peripheral driver circuit 710 is disposed to output the second scan signal line SCAN2 to the driver circuit 200. That is, different transistors 210 in the driver circuit may have different working processes, and different control signals may be required to be input into different transistors 210 and thus different peripheral driver circuits 710 are required. Further, the transistors 210 in the driver circuit 200 are of different types, that is, when a low temperature poly-silicon transistor and an indium gallium zinc oxide transistor are included, different peripheral driver circuits 710 are required to supply different types of control signals to different transistors 210, and enable levels for controlling the preceding transistors 210 of different types are also different. Therefore, arrangements of the peripheral driver circuits 710 are diversified.

Exemplarily, a peripheral driver circuit 710 may be an “8T2C” circuit, a “12T3C” circuit, or a “15T4C” circuit. A “T” and a “C” represent a first transistor 230 and a capacitor in a peripheral driver circuit 710 respectively. Exemplarily, FIG. 17 illustrates an example of a “12T3C” circuit. The arrangement of the peripheral driver circuits 710 may be adjusted adaptively according to needs.

Illustratively, referring to FIGS. 1, 17, and 18, the shielding sub-structures 310 further include a plurality of peripheral shielding sub-structures 330. The transistors 210 in the drive arrays include first transistors 230 in multiple peripheral driver circuits 710. A peripheral shielding sub-structure 330 at least partially overlaps a channel region of a first transistor 230 in a peripheral driver circuit 710. Moreover, the peripheral shielding sub-structures 330 may be connected to some potential signals, that is, electrically connected to some potential signal terminals B (shown as B3 in FIG. 18) to implement the effect of electronic shielding, thereby effectively preventing ions on one side of the substrate 100 from entering each active layer 201 of each first transistor 230, that is, reducing the impact on the working of each channel region, thus guaranteeing the working stability of each peripheral driver circuit 710, guaranteeing the stability and reliability of a signal output by each peripheral driver circuit 710, and thus guaranteeing the driving effect of each driver circuit 200 on a respective light-emitting element 400, that is, guaranteeing the display effect of the display panel 10. A peripheral driver circuit 710 includes a plurality of first transistors 230. The shielding sub-structures 310 include the peripheral shielding sub-structures 330. A channel region of each first transistor 230 in the peripheral driver circuit 710 may overlap a respective peripheral shielding sub-structure 330. Such an arrangement can better guarantee the working stability of the peripheral driver circuit 710, thereby guaranteeing the display effect of the display panel 10.

Illustratively, referring to FIGS. 20 to 22, a region C1 in FIG. 20 illustrates overall layers of a peripheral driver circuit 710. A region D1 in FIG. 21 and a region E1 in FIG. 22 are structural diagrams of part of the layers of the peripheral driver circuit 710 in the region C1 in FIG. 20. The region D1 in FIG. 21 illustrates active layers 233 of multiple first transistors 230. The region E1 in FIG. 22 illustrates multiple peripheral shielding sub-structures 330. A region C2 in FIG. 20 illustrates overall layers of another peripheral driver circuit 710. A region D2 in FIG. 21 and a region E2 in FIG. 22 are structural diagrams of part of the layers of the peripheral driver circuit 710 in the region C2 in FIG. 20. The region D2 in FIG. 21 illustrates active layers 233 of multiple first transistors 230. The region E2 in FIG. 22 illustrates multiple peripheral shielding sub-structures 330. Referring to FIGS. 20 to 22, a peripheral shielding sub-structure 330 corresponds to an active layer 233. In this manner, it is guaranteed that the peripheral shielding sub-structure 330, as a blocking layer, can effectively prevent ions on one side of the substrate 100 from entering the active layer 233 of a first transistor 230, that is, can reduce the impact on the working of a channel region, and it is also guaranteed that a control signal output by a peripheral driver circuit 710 is stable and reliable, thus guaranteeing the working stability of each driver circuit 200, and guaranteeing the display effect of the display panel 10. It is to be noted that FIGS. 20 to 22 each illustrate a structural diagram. Arrangement manners of peripheral driver circuits 710 in different display panels 10 are diversified. No more examples are given here.

With continued reference to FIGS. 1 and 17 to 22, in the same peripheral driver circuit 710, multiple peripheral shielding sub-structures 330 each of which at least partially overlaps a channel region of a respective one of multiple first transistors 230 are electrically connected to each other.

Illustratively, referring to FIGS. 1 and 17, the number of first transistors 230 in a peripheral driver circuit 710 is diversified. FIG. 17 illustrates an example in which a peripheral driver circuit 710 includes twelve first transistors 230.

For the specific layer structure of the peripheral driver circuit 710 shown in FIG. 17, reference may be made to the region C1 in FIG. 20. Further, referring to FIGS. 20 and 22, the same peripheral driver circuit 710 includes multiple peripheral shielding sub-structures 330 which are electrically connected to each other. When a peripheral shielding sub-structure 330 is connected to a potential signal, the peripheral shielding sub-structure 330 may be equivalent to a shielding layer to perform an electric shielding protection on a respective first transistor 230, thereby guaranteeing the working stability of the peripheral driver circuit 710. In the same peripheral driver circuit 710, the multiple peripheral shielding sub-structures 330 at least partially overlapping channel regions of corresponding multiple first transistors 230 are electrically connected to each other. In this case, the multiple peripheral shielding sub-structures 330 in the same peripheral driver circuit 710 are connected to the same potential signal, reducing the number of potential signal terminals B, simplifying the electrical connection between the multiple peripheral shielding sub-structures 330, thereby reducing the process preparation cost of the display panel 10, and improving the enforceability of the display panel 10 provided in the embodiment of the present application.

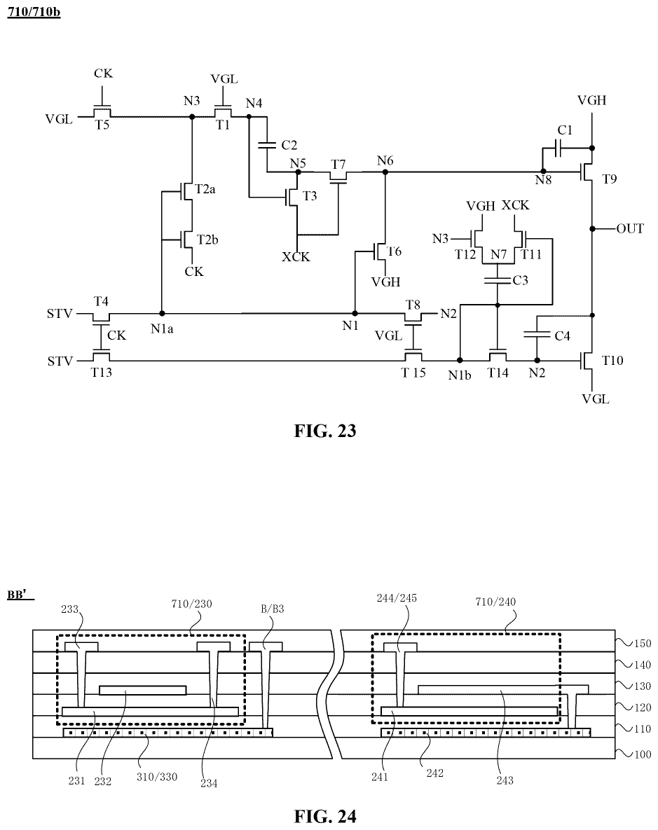

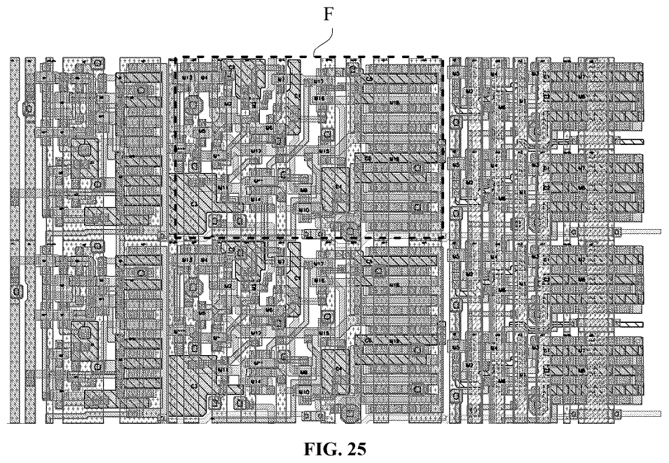

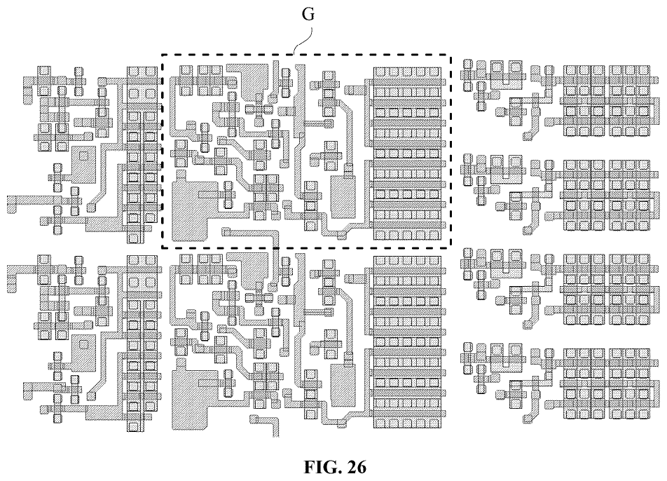

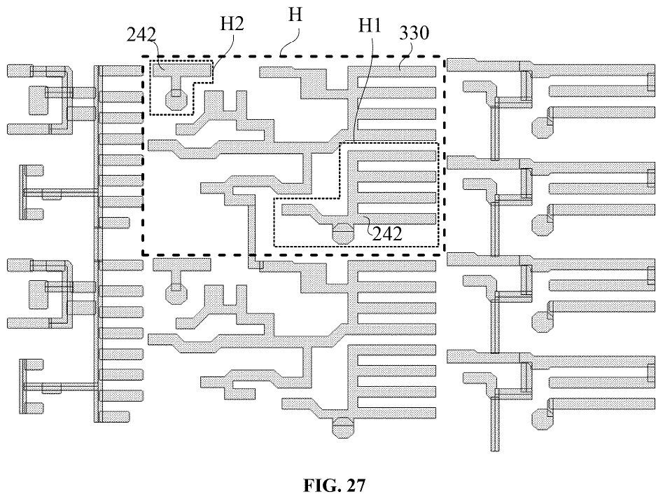

FIG. 23 is a diagram of circuit elements of another peripheral driver circuit according to some embodiments of the present application. FIG. 24 is another sectional view taken along a line B-B′ of FIG. 1. FIG. 25 is a diagram of the layer structure of another peripheral driver circuit according to some embodiments of the present application. FIG. 26 is a partial structural view of FIG. 25. FIG. 27 is another partial structural view of FIG. 25. Referring to FIGS. 1 and 23 to 27, the peripheral driver circuit 710 further includes at least one second transistor 240. A second transistor 240 includes an active layer 241, a bottom gate 242, and a top gate 243. The bottom gate 242 is located between the active layer 241 and the substrate 100. The top gate 243 is located on one side of the active layer 241 facing away from the substrate 100. A bottom gate 242 is electrically connected to a top gate 243 in the same second transistor 240. The bottom gate 242 and a respective peripheral shielding sub-structure 330 are formed in the same layer and are insulated from each other.

The peripheral driver circuit 710 may further include at least one second transistor 240. Referring to FIG. 24, a second transistor 240 includes an active layer 241, a bottom gate 242, a top gate 243, a source 244, and a drain 245. The bottom gate 242 is located between the active layer 241 and the substrate 100. The top gate 243 is located on one side of the active layer 241 facing away from the substrate 100. The second transistor 240 may be understood as a double-gate transistor with a top gate and a bottom gate. Illustratively, referring to FIG. 24, in the same second transistor 240, a bottom gate 242 is electrically connected to a top gate 243, guaranteeing the efficiency of the switch state adjustment of the second transistor 240.

Further, referring to FIG. 24, the bottom gate 242 of the second transistor 240 and the respective peripheral shielding sub-structure 330 may be disposed in the same layer, reducing the number of overall layers of the display panel 10, thereby implementing the thin design of the display panel 10, and reducing the process production cost of the display panel 10. Further, the bottom gate 242 is electrically connected to the top gate 243, thus the bottom gate 242 and the top gate 243 transmit the same signal. The peripheral shielding sub-structure 330 is electrically connected to a potential signal terminal B. In this case, although the bottom gate 242 and the peripheral shielding sub-structure 330 are disposed in the same layer, the insulation between the peripheral shielding sub-structure 330 and the bottom gate 242 needs to be guaranteed, thereby guaranteeing the stable transmission of a signal in the peripheral driver circuit 710 and guaranteeing the overall display effect of the display panel 10.

Illustratively, referring to FIGS. 25 to 27, a region F in FIG. 25 illustrates overall layers of a peripheral driver circuit 710. A region G in FIG. 26 and a region H in FIG. 27 are structural diagrams of part of the layers of the peripheral driver circuit 710 in the region F in FIG. 25. The region G in FIG. 25 illustrates active layers 233 of multiple first transistors 230. The region H in FIG. 27 illustrates multiple peripheral shielding sub-structures 330. Referring to FIGS. 25 to 27, the bottom gate 242 and the peripheral shielding sub-structure 330 are disposed in the same layer, reducing the number of overall layers of the display panel 10, thereby implementing the thin design of the display panel 10, and reducing the process production cost of the display panel 10. Moreover, a peripheral shielding sub-structure 330, as a blocking layer, can effectively prevent ions on one side of the substrate 100 from entering an active layer 233 of a first transistor 230, that is, can reduce the impact on the working of a channel region, guarantee that a control signal output by the peripheral driver circuit 710 is stable and reliable, thus guaranteeing the working stability of each driver circuit 200, and guaranteeing the display effect of the display panel 10. It is to be noted that FIGS. 25 to 27 each illustrate a structural diagram. Arrangement manners of peripheral driver circuits 710 in different display panels 10 are diversified. No more examples are given here.

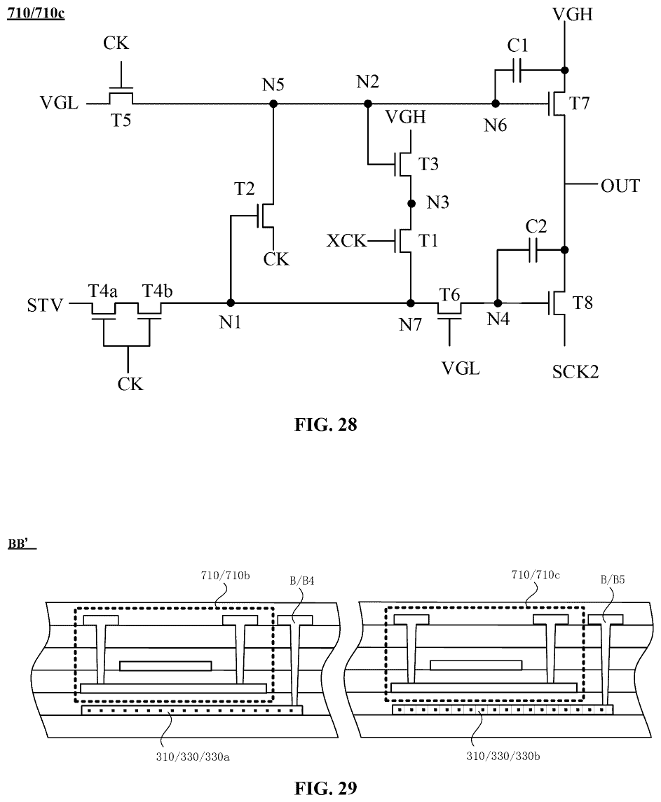

FIG. 28 is a diagram of circuit elements of another peripheral driver circuit according to some embodiments of the present application. FIG. 29 is another sectional view taken along a line B-B′ of FIG. 1. Referring to FIGS. 1 to 3, 19, 23, 28, and 29, the peripheral driver circuits 710 include a first scan driver circuit 710b and a second scan driver circuit 710c. The transistors 210 in the drive arrays include a first scan transistor 251 in a driver circuit 200 and a second scan transistor 252 in the driver circuit 200. The first scan driver circuit 710b is connected to a control terminal of the first scan transistor 251 through a first scan signal line SCAN1. The second scan driver circuit 710c is connected to a control terminal of the second scan transistor 252 through a second scan signal line SCAN2. The peripheral shielding sub-structures 330 include a first peripheral shielding sub-structure 330a and a second peripheral shielding sub-structure 330b. The first peripheral shielding sub-structure 330a corresponds to the first scan driver circuit 710b. The second peripheral shielding sub-structure 330b corresponds to the second scan driver circuit 710c. The first peripheral shielding sub-structure 330a and the second peripheral shielding sub-structure 330b are connected to different potential signal terminals B.

Illustratively, transistors 210 in the driver circuit 200 may include the first scan transistor 251 and the second scan transistor 252. The difference between the first scan transistor 251 and the second scan transistor 252 may be the difference in transistor types. For example, the first scan transistor 251 is an indium gallium zinc oxide transistor, and the second scan transistor 252 is a low temperature poly-silicon transistor. Exemplarily, referring to FIGS. 3 and 19, the first scan transistor 251 may be, for example, the threshold compensation transistor M4 and/or the initialization transistor M5. The second scan transistor 252 may be, for example, the data write transistor M2. The specific arrangement of the first scan transistor 251 and the second scan transistor 252 may be adjusted adaptively according to different driver circuits 200 and is not specifically limited in the embodiment of the present application. In the embodiment, it is to be noted that the first scan signal line SCAN1 is a scan line for electrically connecting the first scan driver circuit 710b to the first scan transistor 251 and the second scan signal line SCAN2 is a scan line for electrically connecting the second scan driver circuit 710c to the second scan transistor 252.

Further, the display panel 10 includes multiple peripheral driver circuits 710. Different peripheral driver circuits 710 may output different control signals. Illustratively, the peripheral driver circuits 710 include the first scan driver circuit 710b and the second scan driver circuit 710c. The first scan driver circuit 710b transmits an output control signal to the first scan transistor 251. The second scan driver circuit 710c transmits an output control signal to the second scan transistor 252. Such an arrangement thus guarantees that the peripheral driver circuits 710 control the driver circuits 200 and drive the light-emitting elements 400, guaranteeing the display effect of the display panel 10.

Exemplarily, referring to FIGS. 3, 19, 23, 28, and 29, the first scan driver circuit 710b is connected to the control terminal of the first scan transistor 251 (exemplarily shown as the initialization transistor M5 in FIG. 3) through the first scan signal line SCAN1. The second scan driver circuit 710c is connected to the control terminal of the second scan transistor 252 (exemplarily shown as the data write transistor M2 in FIG. 3) through the second scan signal line SCAN2.

Further, the peripheral shielding sub-structures 330 may include the first peripheral shielding sub-structure 330a and the second peripheral shielding sub-structure 330b. The first peripheral shielding sub-structure 330a overlaps a channel region of a transistor in the first scan driver circuit 710b. The second peripheral shielding sub-structure 330b overlaps a channel region of a transistor in the second scan driver circuit 710c. Exemplarily, referring to FIG. 29, a section view of the first scan driver circuit 710b and a section view of the second scan driver circuit 710c are both placed in FIG. 29 for ease of observation.

Further, referring to FIG. 29, the first peripheral shielding sub-structure 330a and the second peripheral shielding sub-structure 330b are disposed in different peripheral driver circuits 710 respectively. In this case, the first peripheral shielding sub-structure 330a and the second peripheral shielding sub-structure 330b may be adjusted to be connected to different potential signal terminals B (shown as B4 and B5 in FIG. 29). Illustratively, different peripheral driver circuits 710 may output different control signals, and can be designed in combination with types of actual peripheral driver circuits 710. In general, the potential signals connected to the peripheral shielding sub-structures 330 in the peripheral driver circuits 710 are differentiated according to the differentiation of the peripheral driver circuits 710, better guaranteeing the stability and reliability of signals output by the peripheral driver circuits 710 and thereby guaranteeing the overall display effect of the display panel 10.

Optionally, multiple first transistors 230 are included in the same peripheral driver circuit 710, and multiple peripheral shielding sub-structures 330 overlaps channel regions of corresponding first transistors 230 in the same peripheral driver circuit 710. As mentioned above, the peripheral shielding sub-structures 330 disposed in different peripheral driver circuits 710 may be connected to different potential signals. In this case, it may be considered that different peripheral shielding sub-structures 330 corresponding to channel regions of different first transistors 230 in the same peripheral driver circuit 710 may also be connected to different potential signals, further guaranteeing the stability and reliability of a signal output by the peripheral driver circuit 710.

With continued reference to FIGS. 1, 3, 19, 23, 28, and 30, the first scan transistor 251 includes the initialization transistor M5. The second scan transistor 252 includes the data write transistor M2. A potential signal of the second peripheral shielding sub-structure 330b is greater than a potential signal of the first peripheral shielding sub-structure 330a.

Referring to FIG. 3, in the driver circuit 200, the first scan transistor 251 may be the initialization transistor M5, and the second scan transistor 252 may be the data write transistor M2. The magnitude of a potential signal of a peripheral shielding sub-structure 330 disposed in a respective peripheral driver circuit 710 may be adjusted according to the difference between the first scan transistor 251 in the driver circuit 200 and the second scan transistor 252 in the driver circuit 200. Illustratively, the first peripheral shielding sub-structure 330a overlaps a channel region of a transistor in the first scan driver circuit 710b. The second peripheral shielding sub-structure 330b overlaps a channel region of a transistor in the second scan driver circuit 710c. The potential signal of the second peripheral shielding sub-structure 330b may be adjusted to be greater than the potential signal of the first peripheral shielding sub-structure 330a, thereby guaranteeing that the overall peripheral driver circuits 710 of the display panel 10 can output stable control signals and guaranteeing the display effect of the display panel 10.

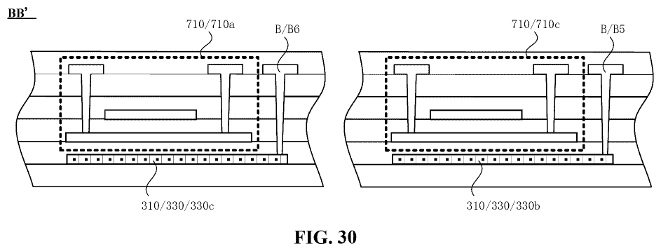

FIG. 30 is another sectional view taken along a line B-B′ of FIG. 1. Referring to FIGS. 1, 3, 17, 19, 28, and 30, the peripheral driver circuits include a second scan driver circuit 710c and a light emission control driver circuit 710a. A driver circuit 200 includes a second scan transistor 252 and a light emission control transistor 253. The second scan driver circuit 710c is connected to a control terminal of the second scan transistor 252 through a second scan signal line SCAN2. The light emission control driver circuit 710a is connected to a control terminal of the light emission control transistor 253 through a light emission control signal line Emit. The peripheral shielding sub-structures 330 include a second peripheral shielding sub-structure 330b and a third peripheral shielding sub-structure 330c. The second peripheral shielding sub-structure 330b corresponds to the second scan driver circuit 710c. The third peripheral shielding sub-structure 330c corresponds to the light emission control driver circuit 710a. The second peripheral shielding sub-structure 330b and the third peripheral shielding sub-structure 330c are connected to different potential signal terminals B.

Illustratively, the driver circuit 200 may include the second scan transistor 252 and the light emission control transistor 253. The difference between the second scan transistor 252 and the light emission control transistor 253 may be the difference in working processes of transistors. For example, the second scan transistor 252 may work when the driver circuit 200 is in a data write stage, and the light emission control transistor 253 may work when the driver circuit 200 is in a light emission control stage. Exemplarily, referring to FIG. 3, the second scan transistor 252 may be, for example, the data write transistor M2. The light emission control transistor 253 may be the light emission control transistor M1 and/or the second light emission control transistor M6. The specific arrangement of the light emission control transistor 253 and the second scan transistor 252 may be adjusted adaptively according to different driver circuits 200 and is not specifically limited in the embodiment of the present application.

Further, the display panel 10 includes multiple peripheral driver circuits 710. Different peripheral driver circuits 710 may output different control signals. Illustratively, the peripheral driver circuits 710 include the second scan driver circuit 710c and the light emission control driver circuit 710a. The second scan driver circuit 710c transmits an output control signal to the second scan transistor 252. The light emission control driver circuit 710a transmits an output control signal to the light emission control transistor 253. Such an arrangement thus guarantees that the peripheral driver circuits 710 control the driver circuits 200 and drive the light-emitting elements 400, guaranteeing the display effect of the display panel 10.

Exemplarily, referring to FIGS. 3, 17, 19, 28, and 30, the second scan driver circuit 710c is connected to the control terminal of the second scan transistor 252 (exemplarily shown as the data write transistor M2 in FIG. 3) through the second scan signal line SCAN2. The light emission control driver circuit 710a is connected to the control terminal of the light emission control transistor 253 (exemplarily shown as the light emission control transistor M1 or M6 in FIG. 3) through the light emission control signal line Emit (exemplarily shown as Emit in FIG. 3).

Further, the peripheral shielding sub-structures 330 may include the second peripheral shielding sub-structure 330b and the third peripheral shielding sub-structure 330c. The second peripheral shielding sub-structure 330b overlaps a channel region of a transistor in the second scan driver circuit 710c. The third peripheral shielding sub-structure 330c overlaps a channel region of a transistor in the light emission control driver circuit 710a. Exemplarily, referring to FIG. 30, a section view of the second scan driver circuit 710c and a section view of the light emission control driver circuit 710a are both placed in FIG. 30 for ease of observation.

Further, referring to FIG. 30, the second peripheral shielding sub-structure 330b and the third peripheral shielding sub-structure 330c are disposed in different peripheral driver circuits 710 respectively. In this case, the second peripheral shielding sub-structure 330b and the third peripheral shielding sub-structure 330c may be adjusted to be connected to different potential signal terminals B (shown as B6 and B5 in FIG. 30). Illustratively, different peripheral driver circuits 710 may output different control signals, and may be designed in combination with types of actual peripheral driver circuits 710. In general, the potential signals connected to the peripheral shielding sub-structures 330 in the peripheral driver circuits 710 are differentiated according to the differentiation of the peripheral driver circuits 710, better guaranteeing the stability and reliability of signals output by the peripheral driver circuits 710 and thereby guaranteeing the overall display effect of the display panel 10.

With continued reference to FIGS. 1, 3, 17, 19, 28, and 30, the second scan transistor 252 includes the data write transistor M2. A potential signal of the third peripheral shielding sub-structure 330c is greater than a potential signal of the second peripheral shielding sub-structure 330b.

Referring to FIG. 3, in the driver circuit 200, the second scan transistor 252 may be the data write transistor M2, and the light emission control transistor 253 may be the light emission control transistor M1. The magnitude of a potential signal of a peripheral shielding sub-structure 330 disposed in a respective peripheral driver circuit 710 may be adjusted according to the difference between the second scan transistor 252 in the driver circuit 200 and the third scan transistor 253 in the driver circuit 200. Illustratively, the second peripheral shielding sub-structure 330b overlaps a channel region of a transistor in the second scan driver circuit 710c. The third peripheral shielding sub-structure 330c overlaps a channel region of a transistor in the light emission control driver circuit 710a. The potential signal of the third peripheral shielding sub-structure 330c may be adjusted to be greater than the potential signal of the second peripheral shielding sub-structure 330b, thereby guaranteeing that the overall peripheral driver circuits 710 of the display panel 10 can output stable control signals and guaranteeing the display effect of the display panel 10.

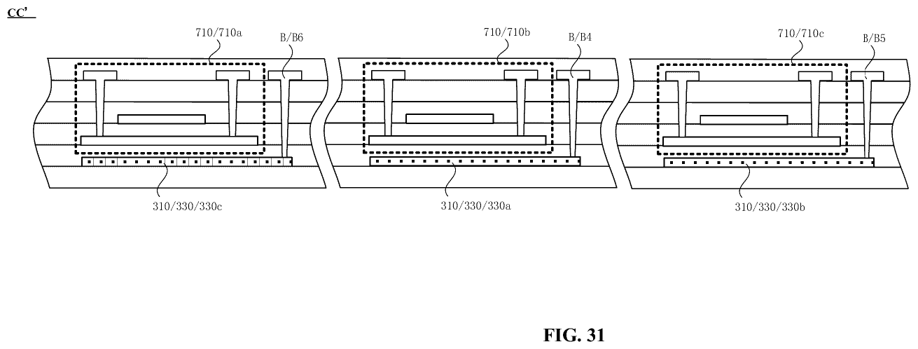

FIG. 31 is another sectional view taken along a line C-C′ of FIG. 19. Referring to FIGS. 1, 3, 17, 19 to 28, and 31, the peripheral driver circuits 710 further include a first scan driver circuit 710b. The driver circuit 200 further includes a first scan transistor 251. The first scan driver circuit 710b is connected to a control terminal of the first scan transistor 251 through a first scan signal line SCAN1. The peripheral shielding sub-structures 330 further include a first peripheral shielding sub-structure 330a corresponding to the first scan driver circuit 710b. The first peripheral shielding sub-structure 330a and the third peripheral shielding sub-structure 330c are connected to different potential signal terminals.

Illustratively, the driver circuit 200 may include the first scan transistor 251, the second scan transistor 252, and the light emission control transistor 253. The corresponding peripheral driver circuits 710 may include the first scan driver circuit 710b, the second scan driver circuit 710c, and the light emission control driver circuit 710a.

Further, the peripheral shielding sub-structures 330 may include the first peripheral shielding sub-structure 330a, the second peripheral shielding sub-structure 330b, and the third peripheral shielding sub-structure 330c. The first peripheral shielding sub-structure 330a overlaps a channel region of a transistor in the first scan driver circuit 710b. The second peripheral shielding sub-structure 330b overlaps a channel region of a transistor in the second scan driver circuit 710c. The third peripheral shielding sub-structure 330c overlaps a channel region of a transistor in the light emission control driver circuit 710a. Exemplarily, referring to FIG. 31, a section view of the first scan driver circuit 710b, a section view of the second scan driver circuit 710c, and a section view of the light emission control driver circuit 710a are placed in FIG. 31 for ease of observation. Referring to FIG. 20 to 22 or 25 to 27, layer structures of three different peripheral driver circuits 710 are illustrated.

Further, referring to FIG. 31, the first peripheral shielding sub-structure 330a, the second peripheral shielding sub-structure 330b, and the third peripheral shielding sub-structure 330c are disposed in different peripheral driver circuits 710 respectively. In this case, the first peripheral shielding sub-structure 330a, the second peripheral shielding sub-structure 330b, and the third peripheral shielding sub-structure 330c may be adjusted to be connected to different potential signal terminals B (shown as B4, B5, and B6 in FIG. 31). Illustratively, different peripheral driver circuits 710 may output different control signals and may be designed in combination with types of actual peripheral driver circuits 710. In general, the potential signals connected to the peripheral shielding sub-structures 330 in the peripheral driver circuits 710 are differentiated according to the differentiation of the peripheral driver circuits 710, better guaranteeing the stability and reliability of signals output by the peripheral driver circuits 710 and thereby guaranteeing the overall display effect of the display panel 10.

With continued reference to FIGS. 1, 3, and 18 to 31, the potential signal of the second peripheral shielding sub-structure 330b is greater than or equal to a potential signal of the first peripheral shielding sub-structure 330a.

Referring to FIG. 3, in the driver circuit 200, the first scan transistor 251 may be the initialization transistor M5, the second scan transistor 252 may be the data write transistor M2, and the light emission control transistor 253 may be the light emission control transistor M1. The magnitudes of potential signals of peripheral shielding sub-structures 330 disposed in corresponding peripheral driver circuits 710 may be adjusted according to the difference between the first scan transistor 251 in the driver circuit 200, the second scan transistor 252 in the driver circuit 200, and the light emission control transistor 253 in the driver circuit 200. Illustratively, the first peripheral shielding sub-structure 330a overlaps a channel region of a transistor in the first scan driver circuit 710b. The second peripheral shielding sub-structure 330b overlaps a channel region of a transistor in the second scan driver circuit 710c. The third peripheral shielding sub-structure 330c overlaps a channel region of a transistor in the light emission control driver circuit 710a. The potential signal of the third peripheral shielding sub-structure 330c may be adjusted to be greater than the potential signal of the second peripheral shielding sub-structure 330b, and the potential signal of the second peripheral shielding sub-structure 330b may be adjusted to be greater than or equal to the potential signal of the first peripheral shielding sub-structure 330a. Therefore, such an arrangement guarantees that the overall peripheral driver circuits 710 of the display panel 10 can output stable control signals, guaranteeing the display effect of the display panel 10.

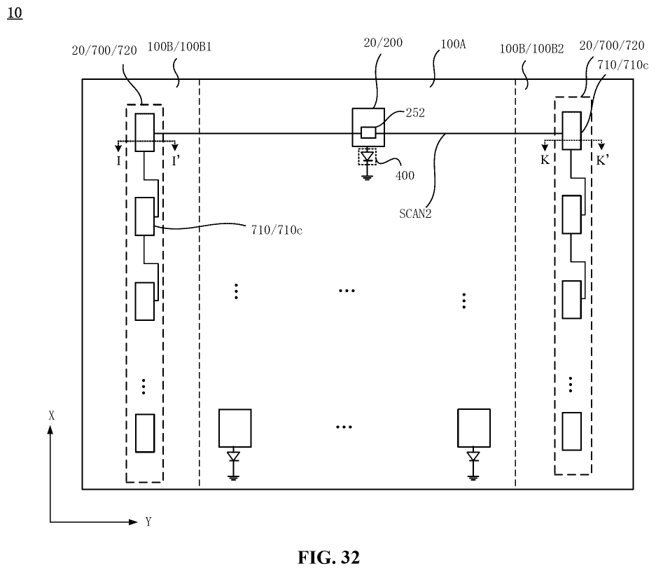

FIG. 32 is a structural diagram of another display panel according to some embodiments of the present application. Referring to FIGS. 3, 28, and 32, the non-display regions 100B include a first non-display region 100B1 and a second non-display region 100B2 located on two opposite sides of the display region 100A respectively. The peripheral circuit groups 700 further include two second scan driver circuit groups 720. One of the two second scan driver circuit groups 720 is located in the first non-display region 100B1. The other one of the two second scan driver circuit groups 720 is located in the second non-display region 100B2. Each second scan driver circuit group 720 includes a plurality of second scan driver circuits 710c arranged in the first direction X in a cascade manner. A driver circuit 200 includes a second scan transistor 252. Each second scan driver circuit 710c is connected to a control terminal of the second scan transistor 252 through a second scan signal line SCAN2. One end of the second scan signal line SCAN2 is connected to second scan driver circuits 710c located in the first non-display region 100B1. The other end of the second scan signal line SCAN2 is connected to second scan driver circuits 710c located in the second non-display region 100B2.

Illustratively, referring to FIG. 32, the non-display regions 100B of the display panel 10 include the first non-display region 100B1 and the second non-display region 100B2 located on two opposite sides of the display region 100A respectively.

Further, the peripheral circuit groups 700 may include second scan driver circuit groups 720. Each second scan driver circuit group 720 includes a plurality of second scan driver circuits 710c arranged in the first direction X in a cascade manner. Referring to FIG. 32, the peripheral circuit groups 700 may include two second scan driver circuit groups 720 located in the first non-display region 100B1 and the second non-display region 100B2 respectively. A second scan driver circuit 710c may be understood as a peripheral driver circuit driven by two sides, guaranteeing the driving effect of the second scan driver circuit 710c and guaranteeing the display effect of the display panel 10.

Illustratively, the driver circuit 200 in the display region 100A includes the second scan transistor 252. The second scan driver circuits 710c located in the first non-display region 100B1 may be connected to a control terminal of the second scan transistor 252 through the second scan signal line SCAN2, and the second scan driver circuits 710c located in the second non-display region 100B2 may also be connected to the control terminal of the second scan transistor 252 through the second scan signal line SCAN2, thus guaranteeing that the driving effect on the driver circuit 200 is more stable.

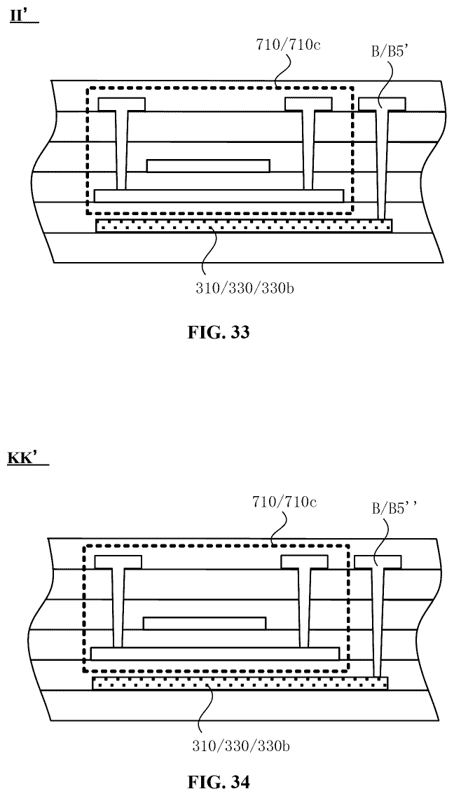

FIG. 33 is a sectional view taken along a line I-I′ of FIG. 32. FIG. 34 is a sectional view taken along a line K-K′ of FIG. 32. Referring to FIGS. 32 to 34, the peripheral shielding sub-structures 330 include second peripheral shielding sub-structures 330b corresponding to the second scan driver circuits 710c. A second peripheral shielding sub-structure 330b located in the first non-display region 100B1 and a second peripheral shielding sub-structure 330b located in the second non-display region 100B2 are connected to different potential signal terminals.

Illustratively, referring to FIGS. 32 to 34, the second scan driver circuits 710c exist in the first non-display region 100B1 and the second non-display region 100B2. Moreover, the peripheral shielding sub-structures 330 include the second peripheral shielding sub-structures 330b corresponding to the second scan driver circuits 710c. That is, each second scan driver circuit 710c located in the first non-display region 100B1 is provided with a second peripheral shielding sub-structure 330b, and each second scan driver circuit 710c located in the second non-display region 100B2 is provided with a second peripheral shielding sub-structure 330b. Such an arrangement guarantees the driving stability of the second scan driver circuits 710c at various positions, guaranteeing the display effect of the display panel 10.

Further, the second scan driver circuits 710c located in the first non-display region 100B1 and the second scan driver circuits 710c located in the second non-display region 100B2 may differ, for example, in arrangement positions or total arrangement numbers, which is not specifically limited in the embodiment of the present application. The second peripheral shielding sub-structure 330b located in the first non-display region 100B1 and the second peripheral shielding sub-structure 330b located in the second non-display region 100B2 may be adjusted to be connected to different potential signal terminals (referring to B5′ in FIGS. 33 and B5′ in FIG. 34). With this arrangement, differentiated potential signals connected to respective second peripheral shielding sub-structures 330b may be adjusted adaptively according to the differentiated arrangement of different second scan driver circuits 710c, thus better guaranteeing the driving effect of the peripheral driver circuits 710 and guaranteeing the overall display effect of the display panel 10.

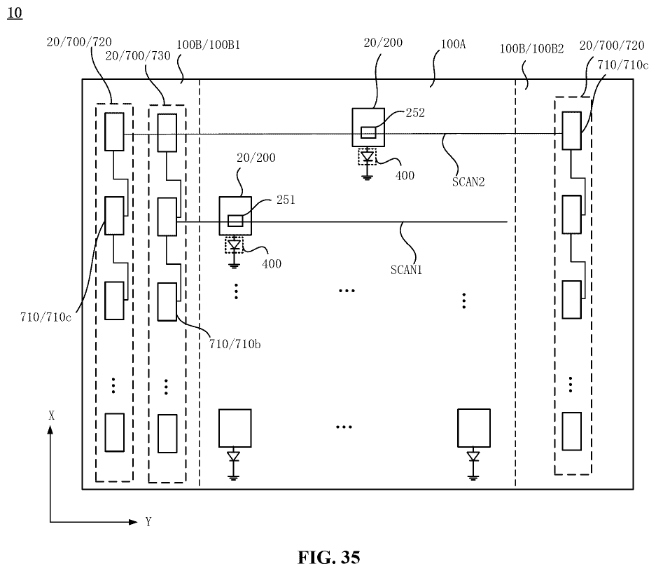

FIG. 35 is a structural diagram of another display panel according to some embodiments of the present application. Referring to FIG. 35, the peripheral circuit groups 700 further include a first scan driver circuit group 730 located in the first non-display region 100B1. The first scan driver circuit group 730 includes a plurality of first scan driver circuits 710b arranged in the first direction X in a cascade manner. A driver circuit 200 includes a first scan transistor 251. A first scan driver circuit 710b is connected to a control terminal of the first scan transistor 251 through a first scan signal line SCAN1. A potential signal of the second peripheral shielding sub-structure 330b located in the second non-display region 100B2 is greater than a potential signal of the second peripheral shielding sub-structure 330b located in the first non-display region 100B1.

Further, the peripheral circuit groups 700 may include the first scan driver circuit group 730. The first scan driver circuit group 730 includes the first scan driver circuits 710b arranged in the first direction X in a cascade manner. Referring to FIG. 35, the first scan driver circuit group 730 may be located in the first non-display region 100B1. A first scan driver circuit 710b may be understood as a peripheral driver circuit driven by a single side. With this arrangement, referring to FIG. 35, the first non-display region 100B1 includes the first scan driver circuit group 730 and a second scan driver circuit group 720, while the second non-display region 100B2 only includes a second scan driver circuit group 720. Therefore, peripheral driver circuits 710 in different non-display regions 100B of the display panel 10 are arranged differentially.

Further, the driver circuit 200 in the display region 100A includes the first scan transistor 251. A first scan driver circuit 710b located in the first non-display region 100B1 may be connected to the control terminal of the first scan transistor 251 through the first scan signal line SCAN1, thereby implementing the driving on the driver circuit 200.

Referring to FIG. 35, the first scan driver circuits 710b are only located in the first non-display region 100B1. In this case, the driving effect of the first scan driver circuits 710b on the driver circuits 200 in the display region 100A may be gradually weakened due to the increase of the load. The driving effect on a driver circuit 200 close to the first scan driver circuit 710b is better than the driving effect on a driver circuit 200 far from the first scan driver circuit 710b. Further, referring to FIG. 35, the second scan driver circuits 710c may exist both in the first non-display region 100B1 and in the second non-display region 100B2, and the peripheral shielding sub-structures 330 include the second peripheral shielding sub-structures 330b corresponding to the second scan driver circuits 710c, respectively. That is, each second scan driver circuit 710c located in the first non-display region 100B1 is provided with a second peripheral shielding sub-structure 330b, and each second scan driver circuit 710c located in the second non-display region 100B2 is provided with a second peripheral shielding sub-structure 330b. With this arrangement, the potential signal of the second peripheral shielding sub-structure 330b located in the second non-display region 100B2 may be adjusted to be greater than the potential signal of the second peripheral shielding sub-structure 330b located in the first non-display region 100B1, guaranteeing the driving effect of the overall peripheral driver circuits 710 on the driver circuits 200.

It may be understood as that the first non-display region 100B1 includes the first scan driver circuits 710b while no first scan driver circuit 710b is disposed in the second non-display region 100B2. Therefore, the driving effect of the first scan driver circuits 710b on the driver circuits 200 in the display region 100A may be gradually weakened due to the increase of the load. The second scan driver circuits 710c are disposed in the first non-display region 100B1 and the second non-display region 100B2. Moreover, the potential signal of the second peripheral shielding sub-structure 330b corresponding to a second scan driver circuit 710c in the second non-display region 100B2 is adjusted to be greater, which is equivalent to the compensation for insufficient driving due to the load problem of the first scan driver circuits 710b, improving driving effect. Such an arrangement can balance the driving effect of the overall peripheral driver circuits 710 on the driver circuits 200, guaranteeing the display effect of the display panel 10.

It is to be noted that the arrangement position of each first scan driver circuit 710b in the first non-display region 100B1 of the display panel 10 and the arrangement position of each second scan driver circuit 710c in the first non-display region 100B1 of the display panel 10 may be adjusted adaptively and are not specifically limited in the embodiment of the present application.

Optionally, a potential signal connected to a respective peripheral shielding sub-structure 330 is V, where 0<V≤4.6v.

Illustratively, the potential signal connected to the peripheral shielding sub-structure 330 may be between 0 and 4.6v. For example, the potential signal may be 1v, 2v, 2.5v, 3v, or 4v. The potential signal connected to the peripheral shielding sub-structure 330 may be adjusted adaptively according to an actual condition.

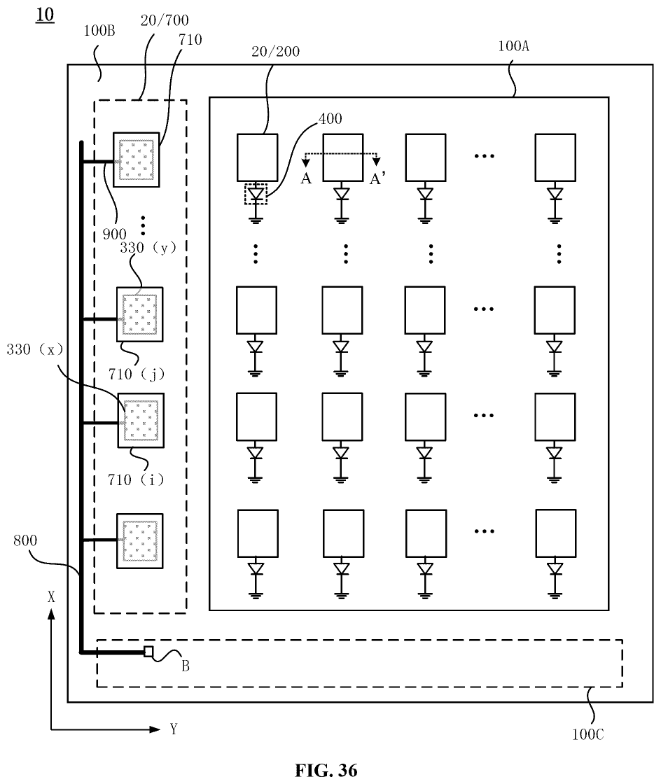

FIG. 36 is a structural diagram of another display panel according to some embodiments of the present application. Referring to FIG. 36, the non-display regions 100B further include a bonding region 100C located in a lower bezel region of the display panel 10. At least one potential signal terminal B is disposed in the bonding region 100C. A peripheral shielding sub-structure 330 is connected to a potential signal terminal B of the at least one potential signal terminal B through a first signal line 800.

Referring to FIG. 36, the non-display regions 100B further include the bonding region 100C. At least one potential signal terminal B is disposed in the bonding region 100C. Each potential signal terminal B is configured to supply a potential signal. Illustratively, referring to FIG. 36, the at least one potential signal terminal B in the bonding region 100C may transmit at least one potential signal to the peripheral shielding sub-structures 330 through the first signal line 800, thus guaranteeing that each shielding sub-structure 330 has a potential signal, performing the function of electric signal shielding, guaranteeing the working stability of the peripheral driver circuits 700, and guaranteeing the display effect of the display panel 10. Electrical connection manners of the peripheral shielding sub-structures 330 and the at least one potential signal terminal B may be diversified. That is, arrangements of the first signal line 800 are diversified.

With continued reference to FIG. 36, a peripheral circuit group 700 includes an i-th peripheral driver circuit 710(i) and a j-th peripheral driver circuit 710(j). The i-th peripheral driver circuit 710(i) is located on one side of the j-th peripheral driver circuit 710(j) facing the bonding region 100C. The peripheral shielding sub-structures 330 include an x-th peripheral shielding sub-structure 330(x) and a y-th peripheral shielding sub-structure 330(y). The x-th peripheral shielding sub-structure 330(x) at least partially overlaps a channel region of a first transistor 230 in the i-th peripheral driver circuit 710(i). The y-th peripheral shielding sub-structure 330(y) at least partially overlaps a channel region of a first transistor 230 in the j-th peripheral driver circuit 710(j). Each of the x-th peripheral shielding sub-structure 330(x) and the y-th peripheral shielding sub-structure 330(y) is connected to the first signal line 800 through a respective patch cord 900. The first signal line 800 extends in the first direction X. The patch cord extends in a second direction Y. The second direction Y intersects the first direction X. The first signal line 800 is located on one side of the peripheral driver circuits 710 facing away from the display region 100A.

Illustratively, referring to FIG. 36, a peripheral circuit group 700 may include a plurality of peripheral driver circuits 710 arranged in the first direction X in a cascade manner. Referring to FIG. 26, the peripheral circuit group 700 includes the i-th peripheral driver circuit 710(i) and the j-th peripheral driver circuit 710(j). Moreover, the i-th peripheral driver circuit 710(i) is closer to the bonding region 100C compared with the j-th peripheral driver circuit 710(j).

Further, the peripheral shielding sub-structures 330 include the x-th peripheral shielding sub-structure 330(x) and the y-th peripheral shielding sub-structure 330(y). The x-th peripheral shielding sub-structure 330(x) at least partially overlaps a channel region of a first transistor 230 in the i-th peripheral driver circuit 710(i). The y-th peripheral shielding sub-structure 330(y) at least partially overlaps a channel region of a first transistor 230 in the j-th peripheral driver circuit 710(j). Combining the positional relationship between the i-th peripheral driver circuit 710(i) and the j-th peripheral driver circuit 710(j), it can be seen that the x-th peripheral shielding sub-structure 330(x) is located on one side of the y-th peripheral shielding sub-structure 330(y) facing the bonding region 100C.

Further, referring to FIG. 36, the display panel 10 includes the first signal line 800 extending in the first direction X. The first signal line 800 is electrically connected to a potential signal terminal B. That is, the first signal line 800 transmits an electric signal supplied by the potential signal terminal B. If the potential signal supplied by the potential signal terminal B connected to a respective peripheral shielding sub-structure 330 is needed, the peripheral shielding sub-structure 330 needs to be adjusted to be electrically connected to the first signal line 800. Illustratively, referring to FIG. 26, the peripheral shielding sub-structure 330 is electrically connected to the first signal line 800 through a respective patch cord 900 extending in the second direction Y. Each of the x-th peripheral shielding sub-structure 330(x) and the y-th peripheral shielding sub-structure 330(y) is connected to the first signal line 800 through a respective patch cord 900. It may be understood as that peripheral shielding sub-structures 330 located in different peripheral driver circuits 710 are each connected to the first signal line 800 through a respective patch cord 900. With this arrangement, the potential signal supplied by the potential signal terminal B is on the transmission path of the first signal line 800 with a small voltage drop, guaranteeing that potential signals received by different peripheral shielding sub-structures 330 are the same or similar, guaranteeing the shielding effect of the peripheral shielding sub-structures 330, guaranteeing the working stability of the peripheral driver circuits 700, and thereby guaranteeing the display effect of the display panel 10.

It is to be noted that a peripheral driver circuit 710 may include a plurality of first transistors 230. Therefore, a region where a respective peripheral shielding sub-structure 330 corresponding to each peripheral driver circuit 710 is located in FIG. 36 may be understood as all the peripheral shielding sub-structures 330 corresponding to the peripheral driver circuit 710.

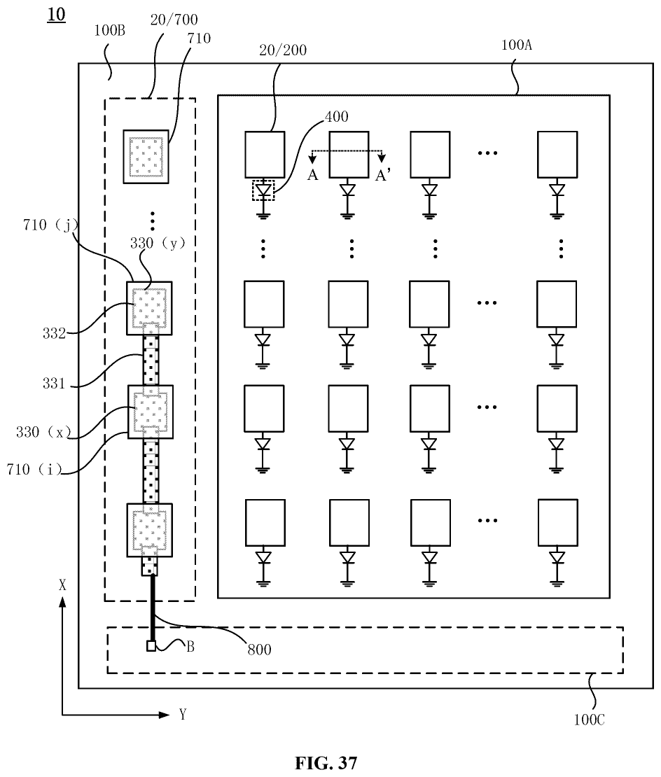

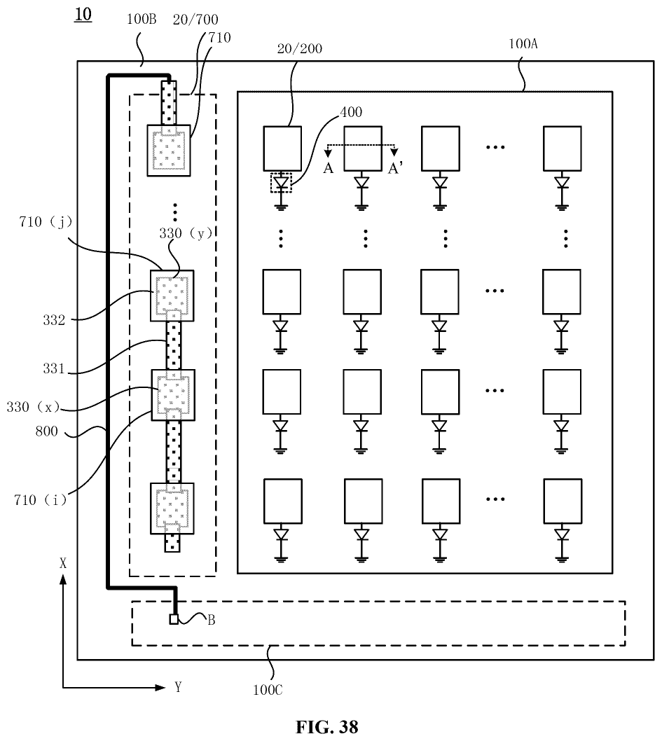

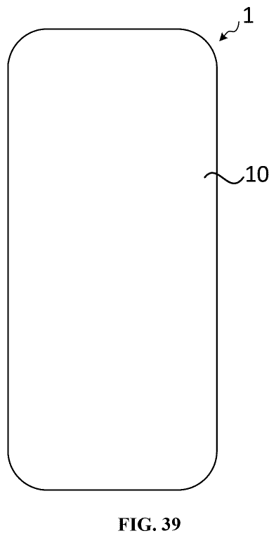

FIG. 37 is a structural diagram of another display panel according to some embodiments of the present application. FIG. 38 is a structural diagram of another display panel according to some embodiments of the present application. Referring to FIGS. 37 and 38, a peripheral circuit group 700 includes an i-th peripheral driver circuit 700(i) and a j-th peripheral driver circuit 700(j). The i-th peripheral driver circuit 700(i) is located on one side of the j-th peripheral driver circuit 700(j) facing the bonding region 100C. The peripheral shielding sub-structures 330 include an x-th peripheral shielding sub-structure 330(x) and a y-th peripheral shielding sub-structure 330(y). The x-th peripheral shielding sub-structure 330(x) at least partially overlaps a channel region of a first transistor in the i-th peripheral driver circuit 710(i). The y-th peripheral shielding sub-structure 330(y) at least partially overlaps a channel region of a first transistor in the j-th peripheral driver circuit 710(j). Each peripheral shielding sub-structure 330 includes a main structure 331 and a plurality of branch structures 332 connected to the main structure 331. Each branch structure 332 at least partially overlaps a channel region of a respective first transistor 230. The x-th peripheral shielding sub-structure 330(x) is connected to the y-th peripheral shielding sub-structure 330(y) through a main structure 331. The x-th peripheral shielding sub-structure 330(x) and the y-th peripheral shielding sub-structure 330(y) are connected to a first signal line 800 through main structures 331.

Further, referring to FIGS. 37 and 38, each peripheral shielding sub-structure 330 includes a main structure 331 and a plurality of branch structures 332. Each branch structure 332 at least partially overlaps a channel region of a respective first transistor 230. Referring to FIGS. 37 and 38, the x-th peripheral shielding sub-structure 330(x) and the y-th peripheral shielding sub-structure 330(y) may be understood as branch structures 332 in the peripheral shielding sub-structures 330. Further, a branch structure 332 is electrically connected to a main structure 331. Referring to FIGS. 37 and 38, a main structure 331 may be understood as a bridge between two adjacent branch structures 332. With this arrangement, a plurality of peripheral driver circuits 710 in the peripheral circuit group 700 are in a cascade manner, and peripheral shielding sub-structures 330 corresponding to various peripheral driver circuits 710 are electrically connected to each other. On this basis, if a potential signal needs to be supplied to a peripheral shielding sub-structure 330, the potential signal can be supplied to a respective main structure 331 to guarantee that the entire peripheral shielding sub-structure 330 has the potential signal, performing shielding effect, guaranteeing the working stability of the peripheral driver circuits 710, and thereby guaranteeing the display effect of the display panel 10.

Illustratively, referring to FIG. 37, a main structure 331 is electrically connected to the first signal line 800. Moreover, the first signal line 800 is electrically connected to a potential signal terminal B, thus guaranteeing that the main structure 331 acquires the potential signal and thereby guaranteeing that a respective entire peripheral shielding sub-structure 330 acquires the potential signal. With this arrangement, no additional wires need to be provided for the electrical connection between various peripheral shielding sub-structures 330 and the first signal line 800, reducing the space occupied by wires in the non-display regions 100B, helping implement narrow bezels of the display panel 10, and saving the process production cost of the display panel 10.

With continued reference to FIGS. 37 and 38, the first signal line 800 is located between the peripheral driver circuits 710 and the bonding region 100C. Alternatively, the first signal line 800 is located on one side of the peripheral driver circuits 710 facing away from the display region 100A and extends in the first direction X. A main structure 331 is connected to one end of the first signal line 800 facing away from the bonding region 100C.

Further, referring to FIG. 37, the first signal line 800 is located between the peripheral driver circuits 710 and the bonding region 100C; that is, the first signal line 800 is electrically connected to the peripheral shielding sub-structures 330 through a main structure 331 close to the bonding region 100C, thereby reducing the extension length of the first signal line 800, saving the space occupied by wires in the non-display regions 100B, helping implement the narrow bezel design of the display panel 10, and reducing the process production cost of the display panel 10. Alternatively, referring to FIG. 38, the first signal line 800 is located on one side of the peripheral driver circuits 710 facing away from the display region 100A and extends in the first direction X. A main structure 331 is connected to one end of the first signal line 800 facing away from the bonding region 100C; that is, the first signal line 800 is electrically connected to the peripheral shielding sub-structures 330 through the main structure 331 away from the bonding region 100C. Such an arrangement reflects the flexible wiring arrangement of the first signal line 800 and may be adjusted adaptively according to needs of different display panels 10.

Based on the same inventive concept, some embodiments of the present application further provides a display device. FIG. 15 is a structural diagram of a display device according to some embodiments of the present application. The display device includes the display panel provided in any of the preceding embodiments. Exemplarily, referring to FIG. 15, the display device 1 includes the display panel 10. Therefore, the display device also has the beneficial effects of the display panel described in the preceding embodiments. For the same details, reference may be made to the description of the preceding display panel, which is not repeated hereinafter.

The touch display device 1 provided in the embodiment of the present application may be a phone shown in FIG. 15 or may be any electronic product with a display function, including, but not limited to: a television, a laptop, a desktop display, a tablet computer, a digital camera, a smart bracelet, smart glasses, an in-vehicle display, industry-controlling equipment, a medical display, a touch interactive terminal and the like, which is not specifically limited in the embodiment of the present application.

What is claimed is:

1. A display panel, comprising a substrate and drive arrays disposed on one side of the substrate and comprising transistors; and
shielding structures disposed on one side of the substrate facing the drive arrays;
wherein each of the shielding structures comprises at least one shielding sub-structure, and a shielding sub-structure among the at least one shielding sub-structure at least partially overlaps a channel region of a respective one of the transistors; and
the shielding sub-structure is connected to a potential signal terminal.

2. The display panel according to claim 1, wherein a drive array of the drive arrays comprises driver circuits, a driver circuit among the driver circuits comprises at least two transistors, and gates of two transistors among the at least two transistors are connected to different control signal terminals;
the shielding structures comprise shielding sub-structures, each of the shielding sub-structures at least partially overlaps a channel region of a respective one of the two transistors; and
different shielding sub-structures are connected to different potential signal terminals.

3. The display panel according to claim 2, wherein the driver circuit comprises a drive transistor and a switch transistor, and a gate of the drive transistor and a gate of the switch transistor are connected to different control signal terminals; and
an output terminal of the drive transistor is electrically connected to an anode of a light-emitting element, and an input terminal of the switch transistor is electrically connected to a display signal line.

4. The display panel according to claim 3, wherein an input terminal of the drive transistor is electrically connected to a first power signal line;
the shielding sub-structures comprise a first shielding sub-structure at least partially overlapping a channel region of the drive transistor; and
the first shielding sub-structure is connected to the first power signal line.

5. The display panel according to claim 3, wherein an output terminal of the switch transistor is connected to a control terminal of the drive transistor at a first node;
the shielding sub-structures comprise a first shielding sub-structure at least partially overlapping a channel region of the drive transistor; and
the first shielding sub-structure is connected to the first node.

6. The display panel according to claim 3, wherein a control terminal of the switch transistor is electrically connected to a gating signal line;
the shielding sub-structures comprise a second shielding sub-structure at least partially overlapping a channel region of the switch transistor; and
the second shielding sub-structure is connected to the gate signal line.

7. The display panel according to claim 6, wherein the gating signal line comprises a scan signal line and a light emission control signal line;
the switch transistor comprises a scan switch transistor and a light emission control switch transistor, a control terminal of the scan switch transistor is electrically connected to the scan signal line, and a control terminal of the light emission control switch transistor is electrically connected to the light emission control signal line;
the second shielding sub-structure comprises a first shielding segment and a second shielding segment, the first shielding segment overlaps a channel region of the scan switch transistor, and the second shielding segment overlaps a channel region of the light emission control switch transistor; and
the first shielding segment is connected to the scan signal line, and the second shielding segment is connected to the light emission control signal line.

8. The display panel according to claim 7, wherein the scan signal line comprises a first scan signal line and a second scan signal line;
the scan switch transistor comprises a first scan transistor and a second scan transistor, a control terminal of the first scan transistor is electrically connected to the first scan signal line, and a control terminal of the second scan transistor is electrically connected to the second scan signal line;
the first shielding segment comprises a first shielding sub-segment and a second shielding sub-segment, the first shielding sub-segment overlaps a channel region of the first scan transistor, and the second shielding sub-segment overlaps a channel region of the second scan transistor; and
the first shielding sub-segment is connected to the first scan signal line, and the second shielding sub-segment is connected to the second scan signal line.

9. The display panel according to claim 2, wherein the driver circuit comprises a switch transistor, a control terminal of the switch transistor is electrically connected to a gating signal line, and the gating signal line comprises a scan signal line and a light emission control signal line;
the switch transistor comprises a scan switch transistor and a light emission control switch transistor, a control terminal of the scan switch transistor is electrically connected to the scan signal line, and a control terminal of the light emission control switch transistor is electrically connected to the light emission control signal line;
the switch transistor is configured to be turned on when a threshold voltage of the switch transistor is less than a gate-source voltage difference of the switch transistor;
the second shielding sub-structure comprises a first shielding segment and a second shielding segment, the first shielding segment overlaps a channel region of the scan switch transistor, and the second shielding segment overlaps a channel region of the light emission control switch transistor; and
a voltage of a potential signal terminal connected to the first shielding segment is greater than a voltage of a potential signal terminal connected to the second shielding segment.

10. The display panel according to claim 9, further comprising a peripheral driver circuit group, a first level signal line, and a second level signal line, wherein the first level signal line and the second level signal line are electrically connected to the peripheral driver circuit group, and a voltage of the first level signal line is greater than a voltage of the second level signal line;
the first shielding segment is connected to the first level signal line; and
the second shielding segment is connected to the second level signal line.

11. The display panel of claim 10, comprising a display region and a non-display region surrounding at least a part of the display region, wherein
the first shielding segment located in the display region is electrically connected through a first connection structure to the first level signal line located in the non-display regions; and
the second shielding segment located in the display region is electrically connected through a second connection structure to the second level signal line located in the non-display regions.

12. The display panel according to claim 9, wherein an input terminal of the drive transistor is electrically connected to a first power signal line, and a cathode of the light-emitting element is electrically connected to a second power signal line;
the first shielding segment is connected to the first power signal line; and
the second shielding segment is connected to the second power signal line.

13. The display panel according to claim 2, wherein the driver circuit comprises a switch transistor, a control terminal of the switch transistor is electrically connected to a gating signal line, and the gating signal line comprises a scan signal line and a light emission control signal line;
the switch transistor comprises a scan switch transistor and a light emission control switch transistor, a control terminal of the scan switch transistor is electrically connected to the scan signal line, and a control terminal of the light emission control switch transistor is electrically connected to the light emission control signal line;
the switch transistor is configured to be turned on when a threshold voltage of the switch transistor is greater than a gate-source voltage difference of the switch transistor;
the second shielding sub-structure comprises a first shielding segment and a second shielding segment, the first shielding segment overlaps a channel region of the scan switch transistor, and the second shielding segment overlaps a channel region of the light emission control switch transistor; and
a voltage of a potential signal terminal connected to the first shielding segment is less than a voltage of a potential signal terminal connected to the second shielding segment.

14. The display panel according to claim 1, comprising a display region and non-display regions, and the non-display regions are located on two sides of the display region, wherein
the drive arrays comprise driver circuits located in the display region and peripheral circuit groups located in the non-display regions, a peripheral circuit group among the peripheral circuit groups comprises a plurality of peripheral driver circuits arranged in a first direction in a cascade manner, and a peripheral driver circuit among the plurality of peripheral driver circuits comprises a plurality of first transistors; and
the shielding structures comprise shielding sub-structures, the shielding sub-structures comprise a plurality of peripheral shielding sub-structures, and each of the plurality of peripheral shielding sub-structures at least partially overlaps a channel region of a respective first transistor;
wherein the first direction is parallel to a plane where the substrate is located.

15. The display panel according to claim 14, wherein in a same peripheral driver circuit among the plurality of peripheral driver circuits, multiple peripheral shielding sub-structures each of which at least partially overlaps a channel region of a respective one of multiple first transistors are electrically connected to each other.

16. The display panel according to claim 15, wherein the peripheral driver circuit further comprises at least one second transistor;
one of the at least one second transistor comprises an active layer, a bottom gate, and a top gate;
the bottom gate is located between the active layer and the substrate; the top gate is located on one side of the active layer facing away from the substrate; and a bottom gate is electrically connected to a top gate in a same one of the at least one second transistor; and
the bottom gate and a respective one of the plurality of peripheral shielding sub-structures are formed in the same layer and are insulated from each other.

17. The display panel according to claim 14, wherein the peripheral driver circuits comprise a first scan driver circuit and a second scan driver circuit, and a driver circuit among the driver circuits comprises a first scan transistor and a second scan transistor;
the first scan driver circuit is connected to a control terminal of the first scan transistor through a first scan signal line, and the second scan driver circuit is connected to a control terminal of the second scan transistor through a second scan signal line;
the plurality of peripheral shielding sub-structures comprise a first peripheral shielding sub-structure and a second peripheral shielding sub-structure, wherein the first peripheral shielding sub-structure corresponds to the first scan driver circuit, and the second peripheral shielding sub-structure corresponds to the second scan driver circuit; and
the first peripheral shielding sub-structure and the second peripheral shielding sub-structure are connected to different potential signal terminals.

18. The display panel according to claim 17, wherein the first scan transistor comprises an initialization transistor, and the second scan transistor comprises a data write transistor; and
a potential signal of the second peripheral shielding sub-structure is greater than a potential signal of the first peripheral shielding sub-structure.

19. The display panel according to claim 14, wherein the peripheral driver circuits comprise a second scan driver circuit and a light emission control driver circuit, and a driver circuit among the driver circuits comprises a second scan transistor and a light emission control transistor;
the second scan driver circuit is connected to a control terminal of the second scan transistor through a second scan signal line, and the light emission control driver circuit is connected to a control terminal of the light emission control transistor through a light emission control signal line;
the plurality of peripheral shielding sub-structures comprise a second peripheral shielding sub-structure and a third peripheral shielding sub-structure, wherein the second peripheral shielding sub-structure corresponds to the second scan driver circuit, and the third peripheral shielding sub-structure corresponds to the light emission control driver circuit; and
the second peripheral shielding sub-structure and the third peripheral shielding sub-structure are connected to different potential signal terminals.

20. The display panel according to claim 19, wherein the second scan transistor comprises a data write transistor; and
a potential signal of the third peripheral shielding sub-structure is greater than a potential signal of the second peripheral shielding sub-structure.

21. The display panel according to claim 19, wherein the peripheral driver circuits further comprise a first scan driver circuit, the driver circuit further comprises a first scan transistor, and the first scan driver circuit is connected to a control terminal of the first scan transistor through a first scan signal line;
the plurality of peripheral shielding sub-structures further comprise a first peripheral shielding sub-structure corresponding to the first scan driver circuit; and
the first peripheral shielding sub-structure and the third peripheral shielding sub-structure are connected to different potential signal terminals.

22. The display panel according to claim 21, wherein the potential signal of the second peripheral shielding sub-structure is greater than or equal to a potential signal of the first peripheral shielding sub-structure.

23. The display panel according to claim 14, wherein the non-display regions comprise a first non-display region and a second non-display region located on two opposite sides of the display region respectively;
the peripheral circuit groups further comprise two second scan driver circuit groups, one of the two second scan driver circuit groups is located in the first non-display region, another one of the two second scan driver circuit groups is located in the second non-display region, and each of the two second scan driver circuit groups comprises a plurality of second scan driver circuits arranged in the first direction in a cascade manner; and
a driver circuit among the driver circuits comprises a second scan transistor, each of the plurality of second scan driver circuits is connected to a control terminal of the second scan transistor through a second scan signal line, one end of the second scan signal line is connected to second scan driver circuits located in the first non-display region, and another end of the second scan signal line is connected to second scan driver circuits located in the second non-display region.

24. The display panel according to claim 23, wherein the plurality of peripheral shielding sub-structures comprise second peripheral shielding sub-structures corresponding to the plurality of second scan driver circuits; and
a second peripheral shielding sub-structure among the second peripheral shielding sub-structures and located in the first non-display region and a second peripheral shielding sub-structure among the second peripheral shielding sub-structures and located in the second non-display region are connected to different potential signal terminal.

25. The display panel according to claim 24, wherein the peripheral circuit groups further comprise a first scan driver circuit group located in the first non-display region and comprising a plurality of first scan driver circuits arranged in the first direction in a cascade manner;
a driver circuit among the driver circuits comprises a first scan transistor, and a first scan driver circuit among the plurality of first scan driver circuits is connected to a control terminal of the first scan transistor through a first scan signal line; and
a potential signal of the second peripheral shielding sub-structure located in the second non-display region is greater than a potential signal of the second peripheral shielding sub-structure located in the first non-display region.

26. The display panel according to claim 14, wherein a potential signal connected to a respective one of the plurality of peripheral shielding sub-structures is V,
wherein 0<V≤4.6v.

27. The display panel according to claim 14, wherein
the non-display regions further comprise a bonding region located in a lower bezel region of the display panel, wherein at least one potential signal terminal is disposed in the bonding region; and
a peripheral shielding sub-structure among the plurality of peripheral shielding sub-structures is connected to a potential signal terminal among the at least one potential signal terminal through a first signal line.

28. The display panel according to claim 27, wherein the peripheral circuit group comprises an i-th peripheral driver circuit and a j-th peripheral driver circuit among the plurality of peripheral driver circuits, and the i-th peripheral driver circuit is located on one side of the j-th peripheral driver circuit facing the bonding region;
the plurality of peripheral shielding sub-structures comprise an x-th peripheral shielding sub-structure and a y-th peripheral shielding sub-structure, the x-th peripheral shielding sub-structure at least partially overlaps a channel region of a first transistor in the i-th peripheral driver circuit, and the y-th peripheral shielding sub-structure at least partially overlaps a channel region of a first transistor in the j-th peripheral driver circuit; and
each of the x-th peripheral shielding sub-structure and the y-th peripheral shielding sub-structure is connected to a first signal line among the first signal lines through a respective patch cord;
wherein the first signal line extends in the first direction, the patch cord extends in a second direction, the second direction intersects the first direction, and the first signal line is located on one side of the plurality of peripheral driver circuits facing away from the display region.

29. The display panel according to claim 27, wherein the peripheral circuit group comprises an i-th peripheral driver circuit and a j-th peripheral driver circuit among the plurality of peripheral driver circuits, and the i-th peripheral driver circuit is located on one side of the j-th peripheral driver circuit facing the bonding region;
the plurality of peripheral shielding sub-structures comprise an x-th peripheral shielding sub-structure and a y-th peripheral shielding sub-structure, the x-th peripheral shielding sub-structure at least partially overlaps a channel region of a first transistor in the i-th peripheral driver circuit, and the y-th peripheral shielding sub-structure at least partially overlaps a channel region of a first transistor in the j-th peripheral driver circuit; and
each of the plurality of peripheral shielding sub-structures comprises a main structure and a plurality of branch structures connected to the main structure, each of the plurality of branch structures at least partially overlaps a channel region of a respective one of the plurality of first transistors, the x-th peripheral shielding sub-structure is connected to the y-th peripheral shielding sub-structure through a main structure, and the x-th peripheral shielding sub-structure and the y-th peripheral shielding sub-structure are connected to a first signal line among the first signal lines through main structures.

30. The display panel according to claim 29, wherein the first signal line is located between the plurality of peripheral driver circuits and the bonding region; or
the first signal line is located on one side of the plurality of peripheral driver circuits facing away from the display region and extends in the first direction, and a main structure is connected to one end of the first signal line facing away from the bonding region.

31. A display device, comprising a display panel, wherein the display panel comprising a substrate and drive arrays disposed on one side of the substrate and comprising transistors, and shielding structures disposed on one side of the substrate facing the drive arrays;
wherein each of the shielding structures comprises at least one shielding sub-structure, and a shielding sub-structure among the at least one shielding sub-structure at least partially overlaps a channel region of a respective one of the transistors; and
the shielding sub-structure is connected to a potential signal terminal.
